(19) United States
(12) Patent Application Publication
(10) Pub. No.: US 2025/0393458 A1
(43) Pub. Date: Dec. 25, 2025

(54) DISPLAY DEVICE, WEARABLE ELECTRONIC DEVICE, AND METHOD OF MANUFACTURING DISPLAY DEVICE

(71) Applicant: Samsung Display Co., Ltd., Yongin-si (KR)

(72) Inventors: Seung Bo SHIM, Yongin-si (KR); Hyo Jung KIM, Yongin-si (KR); Yoo Young PARK, Yongin-si (KR); Hye Sun SUNG, Yongin-si (KR); Ji Hyeon SON, Yongin-si (KR); Mun Cheol LEE, Yongin-si (KR); Jeong Yong LEE, Yongin-si (KR)

(21) Appl. No.: 19/212,057

(22) Filed: May 19, 2025

(30) Foreign Application Priority Data
Jun. 19, 2024 (KR) 10-2024-0079602
Sep. 5, 2024 (KR) 10-2024-0121062

(51) Int. Cl. H10K 59/88; G02B 27/01; H10K 50/19; H10K 59/12; H10K 59/122

(52) U.S. Cl. CPC H10K 59/88; G02B 27/0172; H10K 50/19; H10K 59/1201; H10K 59/122; G02B 2027/0132

(57) ABSTRACT

A display device includes a substrate defining a first sub-pixel and a second sub-pixel which are adjacent to each other. Each of the first sub-pixel and the second sub-pixel includes a first electrode. The display device further includes a pixel-defining layer on the first electrodes; a first emission component to emit light and on the first electrodes and the pixel-defining layer; a first intermediate layer on the first emission component; a second emission component to emit light and on the first intermediate layer; and a second electrode on the second emission component. At least part of the pixel-defining layer may be recessed to form a trench in a boundary area of the first sub-pixel and the second sub-pixel. A dummy pattern may be between the first intermediate layer and the second electrode in the boundary area. The dummy pattern may be an insulation pattern including an organic material.

### CROSS-REFERENCE TO RELATED PATENT APPLICATION

The present application claims priority to and the benefit of Korean Patent Application Number 10-2024-0079602, filed on Jun. 19, 2024, and Korean Patent Application Number 10-2024-0121062, filed on Sep. 5, 2024, in the Korean Intellectual Property Office, the entire disclosures of both of which are incorporated herein by reference.

### BACKGROUND

### 1. Field

Embodiments of the present disclosure relate to a display device, a wearable electronic device including the display device, and a method of manufacturing the display device.

### 2 Description of the Related Art

With the growing interest in information displays, ongoing research and development efforts are focused on advancing display device technology.

### SUMMARY

Aspects of embodiments of the present disclosure are directed to a display device with enhanced reliability, a wearable electronic device including the display device, and a method of manufacturing the display device.

Additional aspects will be set forth in part in the description which follows and, in part, will be apparent from the description, or may be learned by practice of the presented embodiments of the disclosure.

A display device according to one or more embodiments of the present disclosure includes a substrate defining a first sub-pixel and a second sub-pixel which are adjacent to each other. Each of the first sub-pixel and the second sub-pixel includes a first electrode. The display device further includes a pixel-defining layer arranged on the first electrodes of the first and second sub-pixels; a first emission component to emit light and arranged on the first electrodes of the first and second sub-pixels and the pixel-defining layer; a first intermediate layer arranged on the first emission component; a second emission component to emit light and arranged on the first intermediate layer; and a second electrode arranged on the second emission component. At least part of the pixel-defining layer is recessed to form a trench in a boundary area of the first sub-pixel and the second sub-pixel. A dummy pattern is arranged between the first intermediate layer and the second electrode in the boundary area. The dummy pattern is an insulation pattern including an organic material.

In one or more embodiments, the organic material may include parylene.

In one or more embodiments, the dummy pattern may be arranged directly on the first intermediate layer and the first intermediate layer may be a conductor (e.g., may have conductivity).

In one or more embodiments, the second emission component may include a second hole transporter, a second emission layer, and a second electron transporter sequentially stacked on the first intermediate layer. The dummy pattern may be arranged between the first intermediate layer and the second hole transporter.

In one or more embodiments, the second emission component may include a second hole transporter, a second emission layer, and a second electron transporter sequentially stacked on the first intermediate layer. The dummy pattern may be arranged on the second hole transporter.

In one or more embodiments, the dummy pattern may be arranged between the second emission component and the second electrode.

In one or more embodiments, the first emission component and the first intermediate layer may be disconnected at the trench. The second emission component at the first sub-pixel and the second emission component at the second sub-pixel may be connected. The dummy pattern may not be disconnected at the trench.

In one or more embodiments, the dummy pattern may not be arranged on the trench.

In one or more embodiments, the dummy pattern may be positioned in a non-emission area between an emission area of the first sub-pixel and an emission area of the second sub-pixel to correspond to the pixel-defining layer.

In one or more embodiments, the dummy pattern may be positioned across a part of an emission area of the first sub-pixel, a non-emission area between an emission area of the first sub-pixel and an emission area of the second sub-pixel, and a part of the emission area of the second sub-pixel.

In one or more embodiments, the display device may further include a planarization layer arranged below the first electrodes of the first and second sub-pixels. The trench may penetrate through the pixel-defining layer in a non-emission area between an emission area of the first sub-pixel and an emission area of the second sub-pixel and may partially penetrate through the planarization layer. The trench may define a void surrounded by the planarization layer, the first emission component, the first intermediate layer, and the dummy pattern.

In one or more embodiments, the display device may further include a third emission component to emit light and arranged between the first electrode and the first emission component; and a second intermediate layer arranged between the third emission component and the first emission component. The third emission component and the second intermediate layer may each be disconnected at the trench.

In one or more embodiments, the dummy pattern may include a first dummy pattern arranged between the first intermediate layer and the second emission component; and a second dummy pattern arranged between the second intermediate layer and the first emission component.

In one or more embodiments, the second dummy pattern may be disconnected at the trench.

In one or more embodiments, the second dummy pattern may not be arranged on the trench.

In one or more embodiments, the dummy pattern may include a first dummy pattern arranged between the first intermediate layer and the second emission component; and a second dummy pattern arranged between the second emission component and the second electrode.

In one or more embodiments, the display device may further include a planarization layer arranged below the first electrodes of the first and second sub-pixels. The trench may penetrate through the pixel-defining layer in a non-emission area between an emission area of the first sub-pixel and an emission area of the second sub-pixel and may partially penetrate through the planarization layer. The trench may define a void surrounded by the planarization layer, the third emission component, the second intermediate layer, the first emission component, the first intermediate layer, and the dummy pattern.

In one or more embodiments, each of the first emission component to the third emission component may include a hole transporter, an emission layer, and an electronic transporter which are stacked in sequence.

A wearable electronic device according to one or more embodiments of the present disclosure, includes a display panel; and a lens arranged on the display panel. The display panel includes a substrate defining a first sub-pixel and a second sub-pixel arranged adjacent to each other. Each of the first sub-pixel and the second sub-pixel includes a first electrode arranged on the substrate. The display panel further includes a pixel-defining layer arranged on the first electrodes of the first and second sub-pixels; a first emission component to emit light and arranged on the first electrodes of the first and second sub-pixels and the pixel-defining layer; a first intermediate layer arranged on the first emission component; a second emission component to emit light and arranged on the first intermediate layer; and a second electrode arranged on the second emission component. At least part of the pixel-defining layer is recessed to form a trench in a boundary area of the first sub-pixel and the second sub-pixel. A dummy pattern is arranged between the first intermediate layer and the second electrode in the boundary area. The dummy pattern is an organic insulation pattern including parylene.

According to one or more embodiments, the above-described display device is manufactured by forming an anode electrode on a planarization layer on a substrate, the substrate defining sub-pixels; forming a pixel-defining layer on the planarization layer and the anode electrode; forming a first emission component which includes a first emission layer on the anode electrode and the pixel-defining layer; forming a first intermediate layer on the first emission component; disposing a mask above the first intermediate layer and then performing a vacuum deposition process to form a dummy pattern in one area of the first intermediate layer corresponding to a boundary area between adjacent sub-pixels; forming a second emission component including a second emission layer on the dummy pattern; and forming a cathode electrode on the second emission component. The dummy pattern may be an organic insulation pattern including parylene.

A display device and a wearable electronic device according to one or more embodiments may improve reliability by including an insulating dummy pattern (or an organic insulation pattern) on a conductive intermediate layer (or a charge generation layer) in a boundary area (or a non-emission area) between adjacent sub-pixels and thus blocking or reducing current transmitted from the boundary area to the intermediate layer and blocking or reducing laterally leakage through the intermediate layer.

Effects of the embodiments of the present disclosure are not limited by the above, and one or more suitable effects are included in the present specification.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

FIG. 1 is a schematic plan view illustrating a display device according to one or more embodiments of the present disclosure.

FIG. 2 is a schematic exploded perspective view illustrating a part of a display panel of FIG. 1, according to one or more embodiments of the present disclosure.

FIG. 3 is a schematic plan view illustrating one of pixels of FIG. 2, according to one or more embodiments of the present disclosure.

FIG. 4 is a schematic cross-sectional view taken along the line I-l′ of FIG. 3, according to one or more embodiments of the present disclosure.

FIG. 5 is a schematic cross-sectional view illustrating an emission structure included in one of first to third light-emitting elements of FIG. 4, according to one or more embodiments of the present disclosure.

FIG. 6 is a schematic cross-sectional view illustrating an emission structure included in one of first to third light-emitting elements of FIG. 4, according to other embodiments of the present disclosure.

FIG. 7 is a schematic cross-sectional view of an enlarged part of a display device of FIG. 1, according to one or more embodiments of the present disclosure.

FIG. 8 is a schematic cross-sectional view illustrating a part of a light-emitting element layer included in a display device of FIG. 7, according to one or more embodiments of the present disclosure.

FIG. 9 is a schematic cross-sectional view illustrating a method of forming a dummy pattern of FIG. 7, according to one or more embodiments of the present disclosure.

FIG. 10 is a flowchart illustrating a manufacturing method of a display device according to one or more embodiments of the present disclosure.

FIG. 11-FIG. 14 are each a schematic cross-sectional view of an enlarged part of a display device of FIG. 1, according to one or more embodiments of the present disclosure.

FIG. 15-FIG. 19 are schematic cross-sectional views of an enlarged portion of a display device of FIG. 1, according to one or more embodiments of the present disclosure.

FIG. 20 is a schematic block diagram illustrating a display system according to one or more embodiments of the present disclosure.

FIG. 21 is a schematic perspective view illustrating an example of an application of the display system of FIG. 20, according to one or more embodiments of the present disclosure.

FIG. 22 is a schematic view illustrating a user wearing a head mounted display device of FIG. 21, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present.

The terminology used herein is for the purpose of describing particular embodiments only and is not intended to be limiting of the present disclosure. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof. e.g.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. e.g.

In the drawings, the relative sizes of elements, layers, and regions may be exaggerated for clarity. In addition, one or more embodiments may be described with reference to drawings illustrating ideal embodiments. Accordingly, it is to be expected that, for example, shapes may change depending on tolerances and/or manufacturing techniques. Thus, one or more embodiments disclosed herein may not be construed as being limited to the specific shapes depicted, but should be construed as, for example, including variations of the shapes resulting from manufacturing. As such, the shapes depicted in the drawings may not show actual shapes of areas of the device, and the present disclosure is not limited thereto.

Unless otherwise noted, like reference numerals denote like elements throughout the attached drawings and the written description, and thus, duplicative descriptions thereof may not be provided. As used herein, the singular forms “a,” “an” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the third direction DR3 refers to a top-down view of the display panel, as if looking directly down onto the surface from above. In this context, the third direction DR3 is the direction perpendicular or normal to the plane defined by the first direction DR1 and the second direction DR2. This refers to that in a plan view, the arrangement of sub-pixels, pads, and other components as they are laid out on the substrate can be seen, without any perspective distortion.

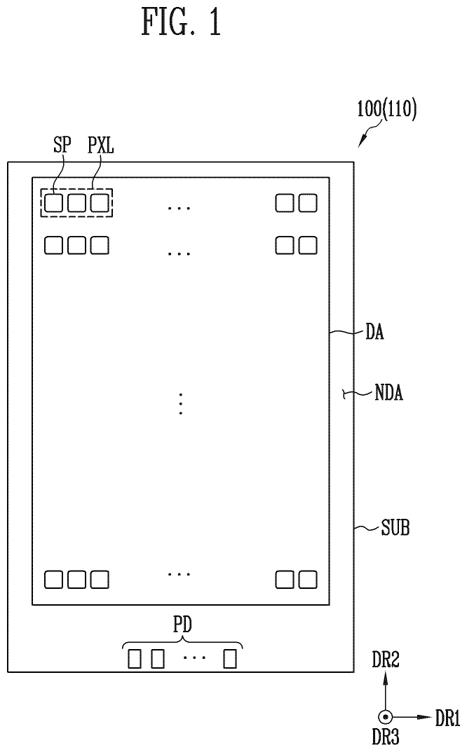

FIG. 1 is a schematic plan view illustrating a display device 100, according to one or more embodiments of the present disclosure. For the sake of convenience, FIG. 1 briefly depicts a structure of the display device 100, for example, a display panel 110 provided in the display device 100 and including a display area DA displaying an image.

Referring to FIG. 1, the display panel 110 may include a display area DA and a non-display area NDA. The display panel 110 may display an image through the display area DA. The non-display area NDA may be arranged around the display area DA.

The display panel 110 may include a substrate SUB, sub-pixels SP, and pads PD.

If the display panel 110 is used as a display screen for a head mounted display (HMD), a virtual reality (VR) device, a mixed reality (MR) device, and/or an augmented reality (AR) device, the display panel 110 may be positioned very close to user's eyes. In such cases, sub-pixels SP of a relatively high density may be desired or required. To increase the density of the sub-pixels SP, the substrate SUB may be provided as a silicon substrate (or a silicon wafer), but the present disclosure is not limited thereto. The sub-pixels SP and/or the display panel 110 may be formed on the substrate SUB which is the silicon substrate. The display device 100 including the display panel 110 formed on the substrate SUB which is the silicon substrate may be referred to as an organic light-emitting diode (OLED) on silicon (OLEDOS) display device.

The sub-pixels SP may be arranged in the display area DA on the substrate SUB. The sub-pixels SP may be arranged in a matrix form along a first direction DR1 and a second direction DR2 intersecting the first direction DR1, but the arrangement form of the sub-pixels SP is not limited thereto. For example, the sub-pixels SP may be arranged in a zigzag pattern along the first direction DR1 and the second direction DR2. For example, the sub-pixels SP may be arranged in a Pentile (PENTILE®) shape (for example, an RGBG matrix, an RGBG structure, or RGBG matrix structure). PENTILE® is a duly registered trademark of Samsung Display Co., Ltd. The first direction DR1 may be a row direction, and the second direction DR2 may be a column direction.

Two or more sub-pixels SP of the plurality of sub-pixels SP may constitute a single pixel PXL.

A component for controlling the sub-pixels SP may be arranged in the non-display area NDA on the substrate SUB. For example, wiring connected to the sub-pixels SP may be arranged in the non-display area NDA. The wiring may include, for example, gate lines, data lines, and/or the like. A driver electrically connected to the sub-pixels SP to drive the sub-pixels SP may be arranged (or integrated) in the non-display area NDA of the display panel 110.

The pads PD may be arranged in the non-display area NDA on the substrate SUB. The pads PD may be electrically connected to the sub-pixels SP through the wiring. For example, the pads PD may be connected to the sub-pixels SP through data lines.

The pads PD may interface the display panel 110 to other components of the display device 100. In one or more embodiments, voltages and signals for operating the components included in the display panel 110 may be provided from the driver (or a driver integrated circuit) via the pads PD. For example, the data lines may be electrically connected to the driver through the pads PD.

In one or more embodiments, a circuit board may be electrically connected to the pads PD, using a conductive adhesive member such as an anisotropic conductive film. In such embodiments, the circuit board may be a flexible circuit board or a flexible film having a flexible material. The driver may be mounted on the circuit board and electrically connected to the pads PD.

In one or more embodiments, the display area DA may have one or more suitable shapes. The display area DA may have a closed loop shape including straight and/or curved sides. For example, the display area DA may have a shape such as a polygon, a circle, a semicircle, and/or an ellipse.

In one or more embodiments, the display panel 110 may have a flat display surface. In one or more embodiments, the display panel 110 may have a display surface which is round at least in part. In one or more embodiments, the display panel 110 may be bendable, foldable, or rollable. In such embodiments, the display panel 110 and/or the substrate SUB may include materials having flexible properties.

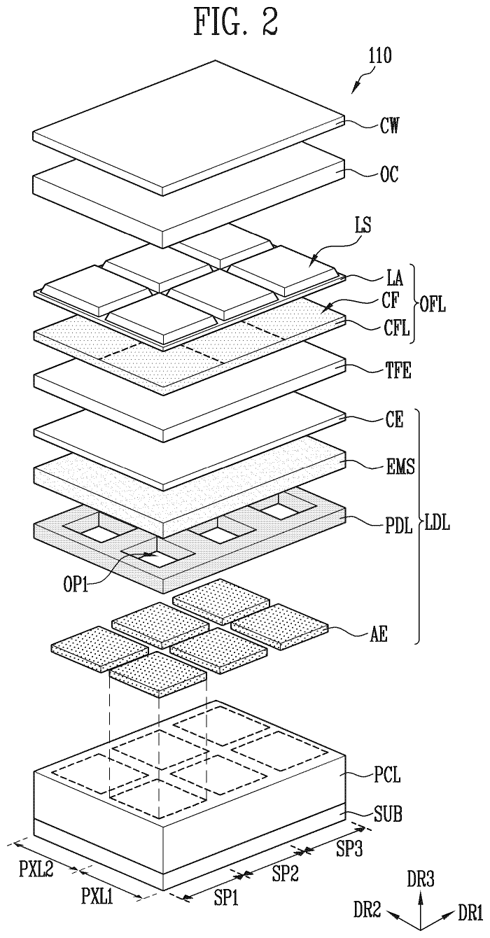

FIG. 2 is a schematic exploded perspective view illustrating a part of the display panel 110 of FIG. 1, according to one or more embodiments of the present disclosure. FIG. 2 briefly illustrates a portion of the display panel 110 corresponding to two pixels PXL1 and PXL2 of the pixels PXL of FIG. 1, for clear and concise explanation. A portion of the display panel 110 corresponding to other pixels PXL may be likewise configured.

Referring to FIG. 1 and FIG. 2, each of the first and second pixels PXL1 and PXL2 may include first to third sub-pixels SP1 to SP3. However, the present disclosure is not limited thereto. For example, each of the first and second pixels PXL1 and PXL2 may include four sub-pixels SP, or may include two sub-pixels SP.

FIG. 2 depicts that the first to third sub-pixels SP1 to SP3 have rectangular shapes, and have the same sizes when viewed from a third direction DR3 crossing the first and second directions DR1 and DR2. However, the present disclosure is not limited thereto. According to one or more embodiments, the first sub-pixel SP1, the second sub-pixel SP2, and the third sub-pixel SP3 may be modified to have one or more suitable shapes.

The display panel 110 may include a substrate SUB, a pixel circuit layer PCL, a light-emitting element layer LDL, an encapsulation layer TFE, an optical functional layer OFL, an overcoat layer OC, and a cover window CW.

In one or more embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, or a semiconductor on insulator (SeOI) layer. In one or more embodiments, the substrate SUB may include a glass substrate. In one or more embodiments, the substrate SUB may include a polyimide (PI) substrate.

The pixel circuit layer PCL may be arranged on the substrate SUB. The substrate SUB and/or the pixel circuit layer PCL may include insulation layers and conductive patterns arranged between the insulation layers. The conductive patterns of the pixel circuit layer PCL may function as at least a part of the circuit elements, wiring, and so on. The conductive patterns may include copper, but the present disclosure is not limited thereto.

The circuit elements may include a sub-pixel circuit of each of the first to third sub-pixels SP1 to SP3. The sub-pixel circuit may include transistors and one or more capacitors. Each transistor may include a semiconductor portion including a source area, a drain area, and a channel area, and a gate electrode superimposed on the semiconductor portion. In one or more embodiments, if the substrate SUB is provided as a silicon substrate, the semiconductor portion may be included in the substrate SUB, and the gate electrode may be included in the pixel circuit layer PCL as a conductive pattern of the pixel circuit layer PCL. In one or more embodiments, if the substrate SUB is provided as a glass substrate or a PI substrate, the semiconductor portion and the gate electrode may be included in the pixel circuit layer PCL. Each capacitor may include electrodes spaced and/or apart (e.g., spaced apart or separated) from each other. For example, each capacitor may include electrodes spaced and/or apart (e.g., spaced apart or separated) from each other on a plane defined by the first and second directions DR1 and DR2 (e.g., in a plan view). In one or more embodiments, each capacitor may include electrodes spaced and/or apart (e.g., spaced apart or separated) from each other in the third direction DR3 with an insulation layer interposed therebetween.

The wiring of the pixel circuit layer PCL may include signal lines connected to the first to third sub-pixels SP1 to SP3, respectively, for example, gate lines, emission control lines, and data lines. According to one or more embodiments, the wires may further include power voltage wiring.

The light-emitting element layer LDL may include an anode electrode AE, a pixel-defining layer PDL, an emission structure EMS, and a cathode electrode CE.

The anode electrode AE may be arranged on the pixel circuit layer PCL. The anode electrode AE may contact the circuit elements of the pixel circuit layer PCL. The anode electrode AE may include an opaque conductive material for reflecting light, but the present disclosure is not limited thereto.

The pixel-defining layer PDL may be disposed on the anode electrode AE. The pixel-defining layer PDL may include a first opening OP1 (e.g., a plurality of first openings OP1) for exposing a part of each anode electrode AE. The first openings OP1 of the pixel-defining layer PDL may be understood as emission areas corresponding to the first to third sub-pixels SP1 to SP3, respectively.

In one or more embodiments, the pixel-defining layer PDL may include an inorganic material. In such embodiments, the pixel-defining layer PDL may include a plurality of stacked inorganic layers. For example, the pixel-defining layer PDL may include silicon oxide (SiOₓ, where 0<x≤2, e.g., SiO₂) and silicon nitride (SiₓN_{y}, where 0<x≤3 and 0<y≤4, e.g., Si₃N₄). In one or more embodiments, the pixel-defining layer PDL may include an organic material. However, the material of the pixel-defining layer PDL is not limited thereto.

The emission structure EMS may be arranged on the anode electrodes AE exposed by the first openings OP1 of the pixel-defining layer PDL. The emission structure EMS may include an emission layer configured to produce light, an electron transport layer configured to transport electrons, and a hole transport layer configured to transport holes.

In one or more embodiments, the emission structure EMS fills the first openings OP1 of the pixel-defining layer PDL, and may be arranged entirely on (e.g., across an entirety of) the pixel-defining layer PDL. For example, the emission structure EMS may extend across the first to third sub-pixels SP1 to SP3. In such embodiments, at least a part of the layers in the emission structure EMS may be disconnected or bent at boundaries between the first to third sub-pixels SP1 to SP3. However, the present disclosure is not limited thereto. For example, parts of the emission structure EMS corresponding to the first to third sub-pixels SP1 to SP3 may be separated from each other, and may be arranged within the first openings OP1 of the pixel-defining layer PDL.

The cathode electrode CE may be arranged on the emission structure EMS. The cathode electrode CE may extend across the first to third sub-pixels SP1 to SP3. As such, the cathode electrode CE may be provided as a common electrode for the first to third sub-pixels SP1 to SP3.

The cathode electrode CE may be a thin metal layer having a thickness for transmitting the light emitted from the emission structure EMS. The cathode electrode CE may be formed with a metallic material to have a relatively small thickness or may be formed with a transparent conductive material. In one or more embodiments, the cathode electrode CE may include at least one of one or more suitable transparent conductive materials, including indium tin oxide, indium zinc oxide, indium tin zinc oxide, aluminum zinc oxide, gallium zinc oxide, zinc tin oxide, and/or gallium tin oxide. In one or more embodiments, the cathode electrode CE may include at least one of silver, magnesium, and/or a (e.g., any suitable) mixture thereof. However, the material of the cathode electrode CE is not limited thereto.

One of the anode electrodes AE, a portion of the emission structure EMS overlapping it, and a portion of the cathode electrode CE overlapping it may be understood as constituting one light-emitting element. For example, each of the light-emitting elements of the first to third sub-pixels SP1 to SP3 may include one anode electrode AE, the portion of the emission structure EMS overlapping it, and the portion of the cathode electrode CE overlapping it. In each of the first to third sub-pixels SP1 to SP3, holes injected from the anode electrode AE and electrons injected from the cathode electrode CE may be transported into the emission layer of the emission structure EMS to form excitons, and light may be generated if the excitons transit from an excited state to a basal state. Luminance of the light may be determined according to the amount of the current flowing through the emission layer. A wavelength range of the produced light may be determined, depending on the configuration of the emission layer.

The encapsulation layer TFE may be arranged on the cathode electrode CE. The encapsulation layer TFE may cover the light-emitting element layer LDL and/or the pixel circuit layer PCL. The encapsulation layer TFE may be configured to prevent or reduce the likelihood of (and/or protect from) oxygen and/or moisture penetrating into the light-emitting element layer LDL. In one or more embodiments, the encapsulation layer TFE may include a structure in which one or more inorganic films and one or more organic films are alternately stacked. For example, the inorganic film may include silicon nitride, silicon oxide, and/or silicon oxynitride. The organic film may include an organic insulation material such as polyacrylates resin, epoxy resin, phenolic resin, polyamide resin, polyimides resin, unsaturated polyesters resin, polyphenylene resin, polyphenylenesulfides resin, and/or benzocyclobutene (BCB) resin. However, the materials of the organic film and the inorganic film of the encapsulation layer TFE are not limited thereto.

To improve encapsulation efficiency of the encapsulation layer TFE, the encapsulation layer TFE may further include a thin film including aluminum oxide (AlₓO_{y}, where 0<x≤2 and 0<y≤3, e.g., Al₂O₃). The thin film including the aluminum oxide may be positioned in a top surface of the encapsulation layer TFE facing (e.g., opposite to) the optical functional layer OFL and/or in a bottom surface of the encapsulation layer TFE facing (e.g., opposite to) the light-emitting element layer LDL.

The thin film including the aluminum oxide may be formed using an atomic layer deposition (ALD) scheme. However, the present disclosure is not limited thereto. The encapsulation layer TFE may further include a thin film formed with at least one of one or more suitable materials suitable for improving the encapsulation efficiency.

The optical functional layer OFL may be arranged on the encapsulation layer TFE. The optical functional layer OFL may include a color filter layer CFL and a lens array LA.

The color filter layer CFL may be arranged between the encapsulation layer TFE and the lens array LA. The color filter layer CFL may be configured to filter the light emitted from the emission structure EMS and selectively output light of the wavelength range or the color corresponding to each sub-pixel SP. The color filter layer CFL includes color filters CF corresponding to the first to third sub-pixels SP1 to SP3, respectively, and the color filters CF may each allow the light of the wavelength range corresponding to the corresponding sub-pixel SP to pass. For example, the color filter CF corresponding to the first sub-pixel SP1 may be to transmit light of a red color, the color filter CF corresponding to the second sub-pixel SP2 may pass light of a green color, and the color filter CF corresponding to the third sub-pixel SP3 may pass light of a blue color. Depending on the light emitted from the emission structure EMS of each sub-pixel SP, at least a part of the color filters CF may not be provided.

The lens array LA may be arranged on the color filter layer CFL. The lens array LA may include lenses LS corresponding to the first to third sub-pixels SP1 to SP3, respectively. The lens LS each may output the light emitted from the emission structure EMS in an intended path, and thus improve light emission efficiency. The lens array LA may have a relatively high refractive index. For example, the lens array LA may have a higher refractive index than the overcoat layer OC. In one or more embodiments, the lenses LS may include an organic material. In one or more embodiments, the lenses LS may include an acrylic (acrylate) material. However, the material of the lenses LS is not limited thereto.

In one or more embodiments, compared to the first openings OP1 of the pixel-defining layer PDL, at least a part of the color filters CF of the color filter layer CFL and at least a part of the lenses LS of the lens array LA may be shifted in a direction parallel to the plane defined by the first and second directions DR1 and DR2. For example, in a central area of the display area DA, a center of the color filters CF and a center of the lenses LS may align or overlap with corresponding centers of the first openings OP1 of the pixel-defining layer PDL when viewed from the third direction DR3 (e.g., in a plan view). For example, in the central area of the display area DA, the first openings OP1 of the pixel-defining layer PDL may fully overlap with the corresponding color filters CF of the color filter layer CFL and the corresponding lenses LS of the lens array LA. In an area adjacent to the non-display area NDA in the display area DA, the center of the color filters CF and the center of the lenses LS may be shifted in a planar direction from the center of the first openings OP1 of the pixel-defining layer PDL when viewed from the third direction DR3 (e.g., in a plan view). For example, in the area adjacent to the non-display area NDA in the display area DA, the first openings OP1 of the pixel-defining layer PDL may partially overlap with the corresponding color filters CF of the color filter layer CFL and the corresponding lenses LS of the lens array LA. Hence, in the center of the display area DA, the light emitted from the emission structure EMS may be efficiently outputted in a normal direction of the display surface. In an outer area of the display area DA, the light emitted from the emission structure EMS may be efficiently outputted in a direction inclined by a specific angle with respect to the normal direction of the display surface. In summary, e.g., the color filters CF and lenses LS in the display device may be shifted relative to the pixel-defining layer's openings. In the central display area, the centers of the color filters CF and lenses LS align with the openings, ensuring efficient light output perpendicular to the display surface. In areas near the non-display region, the centers of the color filters and lenses are shifted, causing partial overlap and directing light at an angle. This design enhances light emission across different display areas.

The overcoat layer OC may be arranged on the lens array LA. The overcoat layer OC may cover the optical functional layer OFL, the encapsulation layer TFE, the emission structure EMS, and/or the pixel circuit layer PCL. The overcoat layer OC may include one or more materials suitable to protect the lower layers of the display panel 110 from foreign substances, such as dust or moisture. For example, the overcoat layer OC may include at least one of an inorganic insulation film and an organic insulation film. For example, the overcoat layer OC may include epoxy resin, but the present disclosure is not limited thereto. The overcoat layer OC may have a lower refractive index than the lens array LA.

The cover window CW may be arranged on the overcoat layer OC. The cover window CW may be configured to protect the lower layers of the display panel 110. The cover window CW may have a higher refractive index than the overcoat layer OC. The cover window CW may include glass, but the present disclosure is not limited thereto. For example, the cover window CW may be an encapsulation glass configured to protect components arranged there below. In one or more embodiments, the cover window CW may not be provided.

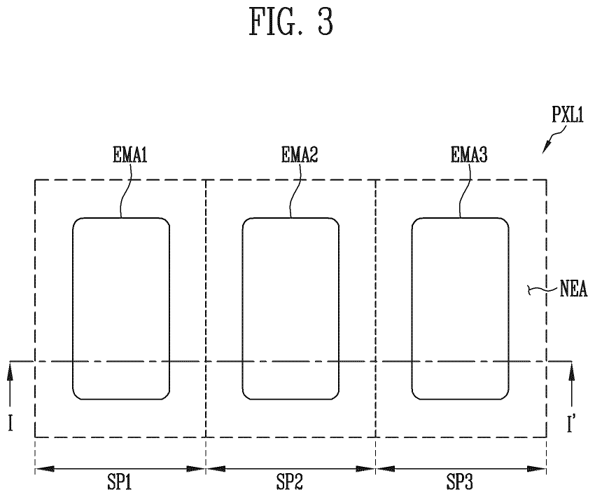

FIG. 3 is a schematic plan view illustrating one of pixels PXL1 and PXL2 of FIG. 2, according to one or more embodiments of the present disclosure. In FIG. 3, the first pixel PXL1 of the first and second pixels PXL1 and PXL2 of FIG. 2 is schematically depicted for clear and concise explanation. The other pixels PXL may be configured in substantially the same manner as the first pixel PXL1.

Referring to FIG. 2 and FIG. 3, the first pixel PXL1 may include the first sub-pixel SP1, the second sub-pixel SP2, and the third sub-pixel SP3 arranged in the first direction DR1.

The first sub-pixel SP1 may include a first emission area EMA1 and a non-emission area NEA around the first emission area EMA1. The second sub-pixel SP2 may include a second emission area EMA2 and the non-emission area NEA around the second emission area EMA2. The third sub-pixel SP3 may include a third emission area EMA3 and the non-emission area NEA around the third emission area EMA3.

The first emission area EMA1 may be an area in which the light is emitted from the portion of the emission structure EMS (see, e.g., FIG. 2) corresponding to the first sub-pixel SP1. The second emission area EMA2 may be an area in which the light is emitted from the portion of the emission structure EMS corresponding to the second sub-pixel SP2. The third emission area EMA3 may be an area in which the light is emitted from the portion of the emission structure EMS corresponding to the third sub-pixel SP3. As described in reference to FIG. 2, each emission area may be understood as the first opening OP1 of the pixel-defining layer PDL corresponding to each of the first to third sub-pixels SP1 to SP3.

The first sub-pixel SP1, the second sub-pixel SP2, and the third sub-pixel SP3 may have substantially the same area, but the present disclosure is not limited thereto. According to one or more embodiments, the second sub-pixel SP2 may have a greater area than the first sub-pixel SP1, and the third sub-pixel SP3 may have a greater area than the second sub-pixel SP2.

The first sub-pixel SP1, the second sub-pixel SP2, and the third sub-pixel SP3 may have a polygonal shape. For example, the first sub-pixel SP1, the second sub-pixel SP2, and the third sub-pixel SP3 may have a rectangular shape or a hexagonal shape, but the present disclosure is not limited thereto. According to one or more embodiments, the first sub-pixel SP1, the second sub-pixel SP2, and the third sub-pixel SP3 may have a circular shape, a semi-elliptic shape, and so on.

The arrangement of the sub-pixels shown in FIG. 3 is an example, and the present disclosure is not limited thereto. Each pixel may include two or more sub-pixels, the sub-pixels may be arranged in one or more suitable fashions, each of the sub-pixels may have one or more suitable shapes, and each of the emission areas of the sub-pixels may also have one or more suitable shapes.

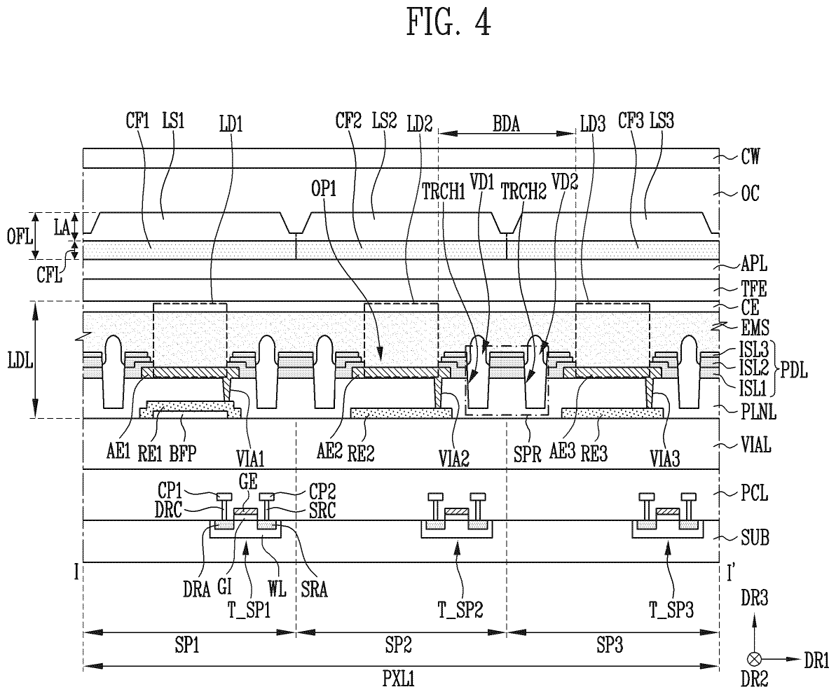

FIG. 4 is a schematic cross-sectional view taken along the line I-I′ of FIG. 3, according to one or more embodiments of the present disclosure.

Referring to FIG. 3 and FIG. 4, the first pixel PXL1 may include the first sub-pixel SP1, the second sub-pixel SP2, and the third sub-pixel SP3. The other pixels PXL throughout the display area DA of the display panel 110 may be configured in substantially the same manner as the first pixel PXL1.

Each of the first to third sub-pixels SP1 to SP3 may include the substrate SUB and the pixel circuit layer PCL arranged on the substrate SUB.

The substrate SUB may include a silicon wafer substrate formed using a semiconductor process. For example, the substrate SUB may include silicon, germanium, and/or silicon-germanium.

The pixel circuit layer PCL may be arranged on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit of the first sub-pixel SP1, the transistor T_SP2 of the second sub-pixel SP2 may be one of the transistors included in the sub-pixel circuit of the second sub-pixel SP2, and the transistor T_SP3 of the third sub-pixel SP3 may be one of the transistors included in the sub-pixel circuit of the third sub-pixel SP3. In FIG. 4, one of the transistors of each sub-pixel SP is depicted for clear and concise explanation, and the other circuit elements may not be provided.

The transistor T_SP1 of the first sub-pixel SP1 may include a source area SRA, a drain area DRA, and a gate electrode GE.

The source area SRA and the drain area DRA may be arranged within the substrate SUB. A well WL is arranged within the substrate SUB through an ion implantation process, and the source area SRA and the drain area DRA may be arranged in the well WL by being spaced and/or apart (e.g., spaced apart and/or separated) from each other. An area between the source area SRA and the drain area DRA within the well WL may be defined as a channel area.

The gate electrode GE may overlap the channel area between the source area SRA and the drain area DRA, and may be arranged in the pixel circuit layer PCL. The gate electrode GE may be spaced from the well WL or the channel area by an insulation material such as a gate insulation layer GI. The gate electrode GE may include a conductive material.

The plurality of layers included in the pixel circuit layer PCL may include insulation layers, and conductive patterns arranged between the insulation layers. The conductive patterns may include a first conductive pattern CP1 and a second conductive pattern CP2. The first conductive pattern CP1 may be electrically connected to the drain area DRA through a drain connector DRC which penetrates one or more insulation layers. The second conductive pattern CP2 may be electrically connected to the source area SRA through a source connector SRC penetrating one or more insulation layers.

As the gate electrode GE, and the first and second conductive patterns CP1 and CP2 are electrically connected to other circuit elements and/or wiring, the transistor T_SP1 of the first sub-pixel SP1 may be provided as one of the transistors configuring the sub-pixel circuit of the first sub-pixel SP1.

The transistor T_SP2 of the second sub-pixel SP2 and the transistor T_SP3 of the third sub-pixel SP3 may each be configured substantially the same as the transistor T_SP1 of the first sub-pixels SP1.

As described above, the substrate SUB and the pixel circuit layer PCL may include the circuit elements of each of the first to third sub-pixels SP1 to SP3.

A via layer VIAL may be arranged on the pixel circuit layer PCL. The via layer VIAL covers the pixel circuit layer PCL, but may have a flat (or substantially uniform) surface in general. For example, a via layer VIAL may be on the pixel circuit layer PCL, and covers the pixel circuit layer PCL and generally has a flat or substantially uniform surface. The via layer VIAL may include at least one of silicon oxide, silicon nitride, and silicon carbon nitride, but the present disclosure is not limited thereto. A light-emitting element layer LDL may be arranged on the via layer VIAL. The light-emitting element layer LDL may include first to third reflective electrodes RE1 to RE3, a planarization layer PLNL, first to third anode electrodes AE1 to AE3, a pixel-defining layer PDL, an emission structure EMS, and a cathode electrode CE.

On the via layer VIAL, the first to third reflective electrodes RE1 to RE3 may be arranged in the first to third sub-pixels SP1 to SP3, respectively. For example, the first reflective electrode RE1 may be arranged on the via layer VIAL of the first sub-pixel SP1, the second reflective electrode RE2 may be arranged on the via layer VIAL of the second sub-pixel SP2, and the third reflective electrode RE3 may be arranged on the via layer VIAL of the third sub-pixel SP3. The first to third reflective electrodes RE1 to RE3 may contact the circuit element arranged in the pixel circuit layer PCL through a via penetrating the via layer VIAL.

The first to third reflective electrodes RE1 to RE3 may function as a full mirror for reflecting the light emitted from the emission structure EMS toward the display surface (or the cover window CW). The first to third reflective electrodes RE1 to RE3 may include at least one of aluminum, silver, magnesium, platinum, palladium, gold, nickel, neodymium, iridium, chromium, and/or titanium. However, the material of the first to third reflective electrodes RE1 to RE3 is not limited to one or more embodiments described above.

The first reflective electrode RE1, the second reflective electrode RE2, and the third reflective electrode RE3 may have the same thickness. For example, the thickness of each of the first reflective electrode RE1, the second reflective electrode RE2, and the third reflective electrode RE3 may be about 700 Å to about 1,000 Å, or about 850 Å, but the present disclosure is not limited thereto.

According to one or more embodiments, a connecting electrode may be arranged below each of the first to third reflective electrodes RE1 to RE3. The connecting electrode may be provided to improve electrical connection characteristics between the corresponding reflective electrode and the circuit element of the pixel circuit layer PCL. The connecting electrode may include multiple layers. For example, the multiple layers may include, but not limited to, a structure in which titanium/titanium nitride, titanium nitride/tantalum nitride, or tantalum nitride are stacked. According to one or more embodiments, the corresponding reflective electrode may be arranged between layers configuring the connecting electrode.

In one or more embodiments, a buffer pattern BFP may be arranged below at least one of the first to third reflective electrodes RE1 to RE3. For example, the buffer pattern BFP may be arranged between the first reflective electrode RE1 and the via layer VIAL. The buffer pattern BFP may include, but is not limited to, an inorganic material such as silicide, carbide, and/or nitride. By disposing the buffer pattern BFP, a height of the corresponding reflective electrode in the third direction DR3 may be adjusted. For example, the buffer pattern BFP may adjust the height of the first reflective electrode RE1 in the third direction DR3. The first reflective electrode RE1 may entirely cover the buffer pattern BFP by covering all of a top surface and both sides (or both ends) (e.g., opposite sides or opposite ends) of the buffer pattern BFP in a cross-sectional view (e.g., in the first and/or second direction DR1 and/or DR2). A part of the first reflective electrode RE1 that is contacting both sides (e.g., opposite sides) of the buffer pattern BFP in a cross-sectional view (e.g., in the first and/or second direction DR1 and/or DR2) may extend to and be in contact with an upper surface of the via layer VIAL For example, a buffer pattern BFP may be arranged below at least one selected from among the first to third reflective electrodes RE1 to RE3. For example, the buffer pattern BFP may be positioned between the first reflective electrode RE1 and the via layer VIAL. The buffer pattern BFP may include inorganic materials such as silicide, carbide, and/or nitride. By incorporating the buffer pattern BFP, the height of the corresponding reflective electrode in the third direction DR3 can be adjusted. For instance, the buffer pattern BFP may adjust the height of the first reflective electrode RE1 in the third direction DR3. The first reflective electrode RE1 may entirely cover the buffer pattern BFP, including its top surface and both sides in a cross-sectional view (e.g., in the first and/or second direction DR1 and/or DR2). Additionally, part of the first reflective electrode RE1, which contacts both sides of the buffer pattern BFP in a cross-sectional view may extend to and contact the upper surface of the via layer VIAL.

In the second sub-pixel SP2, the buffer pattern BFP described above is not arranged between the second reflective electrode RE2 and the via layer VIAL, and the second reflective electrode RE2 may be arranged directly on the via layer VIAL. In one or more embodiments, in the third sub-pixel SP3, the buffer pattern BFP described above is not arranged between the third reflective electrode RE3 and the via layer VIAL, and the third reflective electrode RE3 may be arranged directly on the via layer VIAL.

The first to third reflective electrodes RE1 to RE3 may function as full mirrors, and the cathode electrode CE may function as a half mirror. The light emitted from the emission structure EMS may be amplified at least in part by traveling between the corresponding reflective electrode and the cathode electrode CE, and the amplified light may be outputted through the cathode electrode CE. As such, a distance between each reflective electrode and the cathode electrode CE may be understood as a resonance distance for the light emitted from the emission layer of the corresponding emission structure EMS.

The first sub-pixel SP1 may have a shorter resonance distance than the other sub-pixels SP (e.g., the second and third sub-pixels SP2, SP3) due to the buffer pattern BFP. As such, the adjusted resonance distance may allow the sub-pixel to effectively and efficiently amplify the light of a particular wavelength range (e.g., a red color). Thus, the first sub-pixel SP1 may effectively and efficiently output the light in the corresponding wavelength range.

FIG. 4 depicts that the buffer pattern BFP is provided in the first sub-pixels SP1 and not provided in the second and third sub-pixels SP2 and SP3, but the present disclosure is not limited thereto. According to one or more embodiments, the buffer pattern BFP may be provided in at least one of the second and/or third sub-pixels SP2 and SP3 to adjust the resonance distance of at least one of the second and/or third sub-pixels SP2 and SP3. For example, if the first sub-pixel SP1 is a red sub-pixel, the second sub-pixel SP2 is a green sub-pixel, and the third sub-pixel SP3 is a blue sub-pixel, the distance between the first reflective electrode RE1 and the cathode electrode CE may be longer than the distance between the second reflective electrode RE2 and the cathode electrode CE, and the distance between the second reflective electrode RE2 and the cathode electrode CE may be longer than the distance between the third reflective electrode RE3 and the cathode electrode CE. In other words, red light, having the longest wavelength, should correspond to the longest distance, ensuring efficient light emission for each sub-pixel color. By adjusting the resonance distance, the display device may ensure that each sub-pixel emits light efficiently and with the correct color. This adjustment helps in achieving better color accuracy and brightness. In summary, the resonance distance is tailored for each sub-pixel to match the wavelength of the emitted light, enhancing the display device's performance.

The thickness of the buffer pattern BFP (or the thickness in the third direction DR3) may be about 400 Å to about 600 Å, but the present disclosure is not limited thereto.

The planarization layer PLNL may be provided to planarize steps between the first and third reflective electrodes RE1 and RE3. The planarization layer PLNL may be arranged on the via layer VIAL, and the first to third reflective electrodes RE1 to RE3. The planarization layer PLNL generally covers the first to third reflective electrodes RE1 to RE3 and the via layer VIAL, but may have a flat surface. The planarization layer PLNL may include an insulation material. For example, the planarization layer PLNL may include an inorganic material such as silicon oxide and silicon nitride, but the present disclosure is not limited thereto. According to one or more embodiments, the planarization layer PLNL may not be provided.

In one or more embodiments, the planarization layer PLNL may include a via for exposing an area of the reflective electrode. For example, the planarization layer PLNL may include a first via VIA1 for exposing an area of the first reflective electrode RE1, a second via VIA2 for exposing an area of the second reflective electrode RE2, and a third via VIA3 for exposing an area of the third reflective electrode RE3.

A first anode electrode AE1, a second anode electrode AE2, and a third anode electrode AE3 may be arranged on the planarization layer PLNL. For example, the first anode electrode AE1 may be arranged on the planarization layer PLNL to overlap the first reflective electrode RE1, the second anode electrode AE2 may be arranged on the planarization layer PLNL to overlap the second reflective electrode RE2, and the third anode electrode AE3 may be arranged on the planarization layer PLNL to overlap the third reflective electrode RE3.

The first to third anode electrodes AE1 to AE3 may have similar shapes to the first to third emission areas EMA1 to EMA3 of FIG. 3 when viewed from the third direction DR3 (e.g., in a plan view). For example, the first anode electrode AE1 may have a shape similar to the first emission area EMA1 when viewed from the third direction DR3, the second anode electrode AE2 may have a shape similar to the second emission area EMA2 when viewed from the third direction DR3, and the third anode electrode AE3 may have a shape similar to the third emission area EMA3 when viewed from the third direction DR3, but the present disclosure is not limited thereto.

The first to third anode electrodes AE1 to AE3 each may be electrically connected to a corresponding reflective electrode. For example, the first anode electrode AE1 may be electrically connected to the first reflective electrode RE1 through the first via VIA1 which penetrates the planarization layer PLNL. The second anode electrode AE2 may be electrically connected to the second reflective electrode RE2 through the second via VIA2 that penetrates the planarization layer PLNL. The third anode electrode AE3 may be electrically connected to the third reflective electrode RE3 through the third via VIA3 which penetrates the planarization layer PLNL.

In one or more embodiments, the first anode electrode AE1 may be positioned within the first via VIA1 to directly contact and connect with the first reflective electrode RE1 exposed by the first via VIA1. The second anode electrode AE2 may be positioned within the second via VIA2 to directly contact and connect with the second reflective electrode RE2 exposed by the second via VIA2. The third anode electrode AE3 may be positioned within the third via VIA3 to directly contact and connect with the third reflective electrode RE3 exposed by the third via VIA3.

The first to third anode electrodes AE1 to AE3 may include at least one of transparent conductive materials such as indium tin oxide (ITO), indium zinc oxide (IZO), zinc oxide (ZnOₓ), indium gallium zinc oxide (IGZO), and/or indium tin zinc oxide (ITZO). However, the material of the first to third anode electrodes AE1 to AE3 is not limited thereto. For example, the first to third anode electrodes AE1 to AE3 may include titanium nitride.

In one or more embodiments, the first to third anode electrodes AE1 to AE3 may have the same thickness. For example, the thickness of each of the first anode electrode AE1, the second anode electrode AE2, and the third anode electrode AE3 may range from about 700 Å to about 1000 Å, but the present disclosure is not limited thereto.

Insulation layers for controlling the height of one or more of the first to third anode electrodes AE1 to AE3 may be further provided. The insulation layers may be arranged between one or more of the first to third anode electrodes AE1 to AE3 and corresponding reflective electrodes. In such embodiments, the planarization layer PLNL and/or the buffer pattern BFP may not be provided.

The pixel-defining layer PDL may be arranged on portions of the first to third anode electrodes AE1 to AE3 and the planarization layer PLNL. The pixel-defining layer PDL may include first openings OP1 each for exposing a part of one of the first to third anode electrodes AE1 to AE3, respectively. The first openings OP1 of the pixel-defining layer PDL may define the emission area of each of the first to third sub-pixels SP1 to SP3. The pixel-defining layer PDL may be arranged in the non-emission area NEA (see, e.g., FIG. 3) to define the first emission area EMA1, the second emission area EMA2, and the third emission area EMA3 described in reference to FIG. 3.

In one or more embodiments, the pixel-defining layer PDL may include a plurality of inorganic insulation layers. Each of the plurality of inorganic insulation layers may include at least one of silicon oxide and/or silicon nitride. For example, the pixel-defining layer PDL may include first, second, and third inorganic insulation layers ISL1, ISL2, and ISL3 sequentially stacked, and the first to third inorganic insulation layers ISL1 to ISL3 each may include silicon nitride, silicon oxide, and/or silicon oxynitride. However, the material of the pixel-defining layer PDL is not limited to one or more embodiments described above.

A separator SPR may be provided in a boundary area BDA between neighboring sub-pixels SP. The separator SPR may cause discontinuity to be formed within the emission structure EMS in the boundary area BDA. For example, due to the separator SPR, the emission structure EMS may be disconnected or bent in the boundary area BDA.

The separator SPR may be provided in or on the pixel-defining layer PDL. The pixel-defining layer PDL may include one or more trenches TRCH1 and TRCH2 as the separator SPR in the boundary area BDA. In one or more embodiments, one or more trenches TRCH1 and TRCH2 may be formed by penetrating the pixel-defining layer PDL and partially penetrating the planarization layer PLNL as shown in FIG. 4. In other embodiments, one or more trenches TRCH1 and TRCH2 may penetrate the pixel-defining layer PDL and the planarization layer PLNL and may partially penetrate the via layer VIAL. In other embodiments, one or more trenches TRCH1 and TRCH2 may be formed by partially penetrating the pixel-defining layer PDL.

The two trenches TRCH1 and TRCH2 may be provided in the boundary area BDA. For example, the first trench TRCH1 and the second trench TRCH2 may be provided in the boundary area BDA between the second sub-pixel SP2 and the third sub-pixel SP3. However, the present disclosure is not limited thereto, and one trench may be provided or three or more separated trenches may be provided in the boundary area BDA, according to one or more embodiments.

Due to the first and second trenches TRCH1 and TRCH2, discontinuous portions such as a first void VD1 and a second void VD2 in the boundary area BDA may be formed in the emission structure EMS. A part of the plurality of layers stacked within the emission structure EMS may be disconnected or bent by the first and second voids VD1 and VD2. For example, at least one charge generation layer and at least one hole injection layer included in the emission structure EMS may be disconnected at the first and second voids VD1 and VD2. As such, due to the first and second trenches TRCH1 and TRCH2, the emission structure EMS included in the first to third sub-pixels SP1 to SP3 may be separated at least in part. Depending on the shape of each of the first and second trenches TRCH1 and TRCH2, the shape of the discontinuous portions formed in the emission structure EMS, for example, the first and second voids VD1 and VD2 may be changed in one or more suitable ways.

The first and second trenches TRCH1 and TRCH2 may include or may be defined (or formed) by a portion penetrating the pixel-defining layer PDL and a recessed portion penetrating at least a part of the planarization layer PLNL. The first and second trenches TRCH1 and TRCH2 may be formed using an etching method, for example, a dry etching method, but the present disclosure is not limited thereto. For example, the first and second trenches TRCH1 and TRCH2 may be formed by removing at least a part of the pixel-defining layer PDL and the planarization layer PLNL from the top surface of the pixel-defining layer PDL toward the bottom surface of the planarization layer PLNL.

Depending on the shapes of the first and second trenches TRCH1 and TRCH2, the discontinuous portions formed in the emission structure EMS may be modified in one or more suitable ways.

In one or more embodiments, the emission structure EMS may be formed through a process such as vacuum deposition, or inkjet printing. In such embodiments, the same materials as in the emission structure EMS may be positioned on bottom surfaces adjacent to the via layer VIAL in the first and second trenches TRCH1 and TRCH2. In other words, when the emission structure EMS is deposited, the emission structure EMS at the trenches TRCH1 and TRCH2 may be deposited at the bottom of the trenches TRCH1 and TRCH2 adjacent to the via layer VIAL, thus resulting in the emission structure EMS being at least partially disconnected at the trenches TRCH1 and TRCH2.

The separator SPR may be provided in one or more suitable modifications to allow the emission structure EMS to have the discontinuous portions in the boundary area BDA. In one or more embodiments, without one or more trenches TRCH1 and TRCH2, additional inorganic insulation patterns may be provided on the pixel-defining layer PDL in the boundary area BDA. In one or more embodiments, a width (e.g., a width in the first and/or second direction DR1 and/or DR2) of the inorganic insulation pattern at the top of the stacked inorganic insulation patterns may be greater than a width of the inorganic insulation pattern arranged directly there below. For example, in the boundary area BDA, the first to third inorganic insulation patterns may be sequentially stacked from the top surface of the pixel-defining layer PDL, and the third inorganic insulation pattern at the top may have a greater width than the second inorganic insulation pattern. In such embodiments, the inorganic insulation patterns on the pixel-defining layer PDL may have the cross section in a “T” shape or an “I” shape in the boundary area BDA. According to the shapes of the inorganic insulation patterns on the pixel-defining layer PDL, the plurality of layers included in the emission structure EMS may be at least in part disconnected or bent in the boundary area BDA.

The emission structure EMS may be arranged on anode electrodes AE (see, e.g., of FIG. 2) exposed by the first openings OP1 of the pixel-defining layer PDL. The emission structure EMS fills the first openings OP1 of the pixel-defining layer PDL, but may be arranged over all of (e.g., an entirety of) the first to third sub-pixels SP1 to SP3. As described earlier, the emission structure EMS may be at least in part disconnected or bent by the separator SPR in the boundary area BDA. Hence, in the operation of the display panel 110 (see, e.g., of FIG. 2), the current flowing from each of the first to third sub-pixels SP1 to SP3 to the neighboring sub-pixel SP through the layers included in the emission structure EMS may be reduced. Thus, the first, second, and third light-emitting elements LD1, LD2, and LD3 may operate with relatively high reliability.

The cathode electrode CE may be arranged on the emission structure EMS. The cathode electrode CE may be provided in common to the first to third sub-pixels SP1 to SP3. The cathode electrode CE may function as a half mirror for partially transmitting and partially reflecting the light emitted from the emission structure EMS.

The first anode electrode AE1 (or a first electrode), the portion of the emission structure EMS overlapping the first anode electrode AE1, and the portion of the cathode electrode CE (or a second electrode) overlapping the first anode electrode AE1 may configure (constitute) the first light-emitting element LD1. The second anode electrode AE2 (or a first electrode), the portion of the emission structure EMS overlapping the second anode electrode AE2, and the portion of the cathode electrode CE (or a second electrode) overlapping the second anode electrode AE2 may configure (constitute) the second light-emitting element LD2. The third anode electrode AE3 (or a first electrode), the portion of the emission structure EMS overlapping the third anode electrode AE3, and the portion of the cathode electrode CE (or a second electrode) overlapping the third anode electrode AE3 may configure (constitute) the third light-emitting element LD3.

The encapsulation layer TFE may be arranged on the cathode electrode CE. The encapsulation layer TFE may prevent or reduce the likelihood of (of protect from) oxygen and/or moisture penetrating into the light-emitting element layer LDL.

The optical functional layer OFL may be arranged on the encapsulation layer TFE. In one or more embodiments, the optical functional layer OFL may be attached to the encapsulation layer TFE using an adhesive layer APL. For example, the optical functional layer OFL may be manufactured separately and attached to the encapsulation layer TFE using the adhesive layer APL. The adhesive layer APL may further perform a function of protecting the lower layers including the encapsulation layer TFE.

The optical functional layer OFL may include the color filter layer CFL and the lens array LA.

The color filter layer CFL may include first to third color filters CF1 to CF3 corresponding to the first to third sub-pixels SP1 to SP3, respectively. For example, the color filter layer CFL may include the first color filter CF1 corresponding to the first sub-pixel SP1, the second color filter CF2 corresponding to the second sub-pixel SP2, and the third color filter CF3 corresponding to the third sub-pixel SP3. The first to third color filters CF1 to CF3 may pass light of different wavelength ranges. For example, the first color filter CF1 may pass light of the red color, the second color filter CF2 may pass light of the green color, and the third color filter CF3 may pass light of the blue color. In such embodiments, the first sub-pixel SP1 may be a red sub-pixel, the second sub-pixel SP2 may be a green sub-pixel, and the third sub-pixel SP3 may be a blue sub-pixel.

In one or more embodiments, the first to third color filters CF1 to CF3 may partially overlap in the boundary area BDA. In other embodiments, the first to third color filters CF1 to CF3 may be spaced from each other, and a black matrix may be provided between the spaced first to third color filters CF1 to CF3 in the boundary area BDA.

The lens array LA may be arranged on the color filter layer CFL. The lens array LA may include first to third lenses LS1 to LS3 corresponding to the first to third sub-pixels SP1 to SP3, respectively. For example, the lens array LA may include the first lens LS1 corresponding to the first sub-pixel SP1, the second lens LS2 corresponding to the second sub-pixel SP2, and the third lens LS3 corresponding to the third sub-pixel SP3. The first to third lenses LS1 to LS3 each may output the light emitted from the first to third light-emitting elements LD1 to LD3 in an intended path, thus improving the light emission efficiency.

The overcoat layer OC may be arranged on the optical functional layer OFL, and the cover window CW may be arranged on the overcoat layer OC.

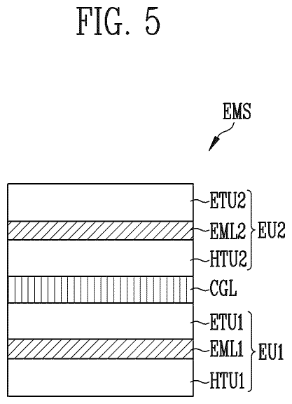

FIG. 5 is a schematic cross-sectional view illustrating an emission structure EMS included in one of the first to third light-emitting elements LD1 to LD3 of FIG. 4, according to one or more embodiments of the present disclosure.

Referring to FIG. 5, the emission structure EMS may have a tandem structure in which a first emission component EU1 and a second emission component EU2 are stacked. The emission structure EMS may be configured substantially the same in each of the first to third light-emitting elements LD1 to LD3 of FIG. 4 and in the remaining pixels PXL throughout the display area DA of the display panel 110.

Each of the first and second emission components EU1 and EU2 may include at least one emission layer for producing light according to an applied current. The first emission component EU1 may include a first emission layer EML1, a first electron transporter ETU1, and a first hole transporter HTU1. The first emission layer EML1 may be arranged between the first electron transporter ETU1 and the first hole transporter HTU1. The second emission component EU2 may include a second emission layer EML2, a second electron transporter ETU2, and a second hole transporter HTU2. The second emission layer EML2 may be arranged between the second electron transporter ETU2 and the second hole transporter HTU2.

Each of the first and second hole transporters HTU1 and HTU2 may include at least one of a hole injection layer and/or a hole transport layer, and may further include a hole buffer layer, an electron blocking layer and/or the like, if desired or required. The first and second hole transporters HTU1 and HTU2 may have the same configuration or different configurations from each other.

Each of the first and second electron transporters ETU1 and ETU2 may include at least one of an electron injection layer and/or an electron transport layer, and may further include an electron buffer layer, a hole blocking layer and/or the like, if desired or required. The first and second electronic transporters ETU1 and ETU2 may have the same configuration or different configurations from each other.

An intermediate layer (or a connection layer) which may be provided in the form of the charge generation layer CGL may be arranged between the first emission component EU1 and the second emission component EU2 to interconnect the first emission component EU1 and the second emission component EU2. Hereinafter, the charge generation layer CGL is referred to as the intermediate layer. In one or more embodiments, the intermediate layer CGL may have a stacked structure of a p-dopant layer and an n-dopant layer. For example, the p-dopant layer may include a p-type (kind) dopant such as hexaazatriphenylenehexacarbonitrile (HAT-CN), tetracyanoquinodimethane (TCNQ), and/or 2-(7-dicyanomethylene-1,3,4,5,6,8,9,10-octafluoro-7H-pyrene-2-ylidene)-malononitrile (NDP-9), and the n-dopant layer may include alkali metal, alkali earth metal, lanthanide-based metal, and/or a (e.g., any suitable) combination thereof. However, the structure (or the material) of the intermediate layer CGL is not limited to one or more embodiments described above. In one or more embodiments, the intermediate layer CGL may be conductive (e.g., may be a conductor) by including a material of relatively higher charge conductivity (or charge mobility) than the first and second emission components EU1 and EU2.

In one or more embodiments, the first emission layer EML1 and the second emission layer EML2 may produce light in different colors. The light emitted from each of the first emission layer EML1 and the second emission layer EML2 may be mixed and recognized as white light. For example, a structure in which a first sub-emission layer configured to produce the blue-colored light at the first emission layer EML1 and to produce the red-colored light at the second emission layer EML2 and a second sub-emission layer configured to produce the green-colored light are stacked may be included. In such embodiments, a functional layer configured to perform a function of transporting holes and/or blocking transport of electrons may be further arranged between the first and second sub-emission layers.

In one or more embodiments, the first emission layer EML1 and the second emission layer EML2 may produce light of the same color.

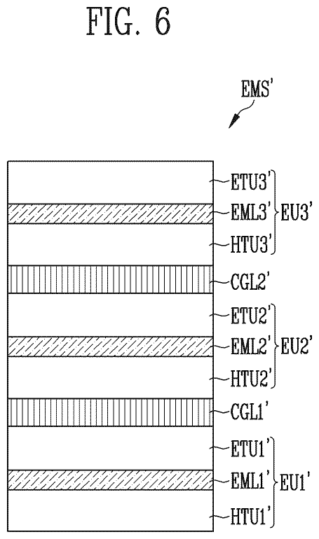

FIG. 6 is a schematic cross-sectional view illustrating an emission structure EMS' included in one of the first to third light-emitting elements LD1 to LD3 of FIG. 4, according to other embodiments of the present disclosure.

Referring to FIG. 4 and FIG. 6, the emission structure EMS' may have a tandem structure in which first, second, and third emission components EU1′, EU2′, and EU3′ are stacked. The emission structure EMS' may be configured substantially the same in each of the first to third light-emitting elements LD1 to LD3 of FIG. 4 and in the remaining pixels PXL throughout the display area DA of the display panel 110.

Each of the first to third emission components EU1′ to EU3′ may include an emission layer for producing light depending on an applied current. The first emission component EU1′ may include a first emission layer EML1′, a first electron transporter ETU1′, and a first hole transporter HTU1′. The first emission layer EML1′ may be arranged between the first electron transporter ETU1′ and the first hole transporter HTU1′. The second emission component EU2′ may include a second emission layer EML2′, a second electron transporter ETU2′, and a second hole transporter HTU2′. The second emission layer EML2′ may be arranged between the second electron transporter ETU2′ and the second hole transporter HTU2′. The third emission component EU3′ may include a third emission layer EML3′, a third electron transporter ETU3′, and a third hole transporter HTU3′. The third emission layer EML3′ may be arranged between the third electron transporter ETU3′ and the third hole transporter HTU3′.

Each of the first to third hole transporters HTU1′ to HTU3′ may include at least one of a hole injection layer and/or a hole transport layer, and may further include, if desired or needed, a hole buffer layer, an electron blocking layer, and/or the like. The first to third hole transporters HTU1′ to HTU3′ may have the same configuration or different configurations.

Each of the first to third electron transporters ETU1′ to ETU3′ may include at least one of an electron injection layer and/or an electron transport layer, and may further include an electron buffer layer, a hole blocking layer, and/or the like, if desired or required. The first to third electronic transporters ETU1′ to ETU3′ may have the same configuration or different configurations.

A first intermediate layer CGL1′ may be arranged between the first emission component EU1′ and the second emission component EU2′. A second intermediate layer CGL2′ may be arranged between the second emission component EU2′ and the third emission component EU3′. In one or more embodiments, the first intermediate layer CGL1′ and the second intermediate layer CGL2′ may be conductive (e.g., may be a conductor) by including a material of a relatively higher charge conductivity (or charge mobility) than the first emission component EU1′, the second emission component EU2′, and the third emission component EU3′.

In one or more embodiments, the first to third emitting layers EML1′ to EML3′ may produce light of different colors. The light emitted from each of the first to third emission layers EML1′ to EML3′ may be mixed and recognized as white light. For example, the first emission layer EML1′ may produce the blue-colored light, the second emission layer EML2′ may produce the green-colored light, and the third emission layer EML3′ may produce the red-colored light.

In one or more embodiments, two or more emission layers of the first to third emission layers EML1′ to EML3′ may produce light of the same color.

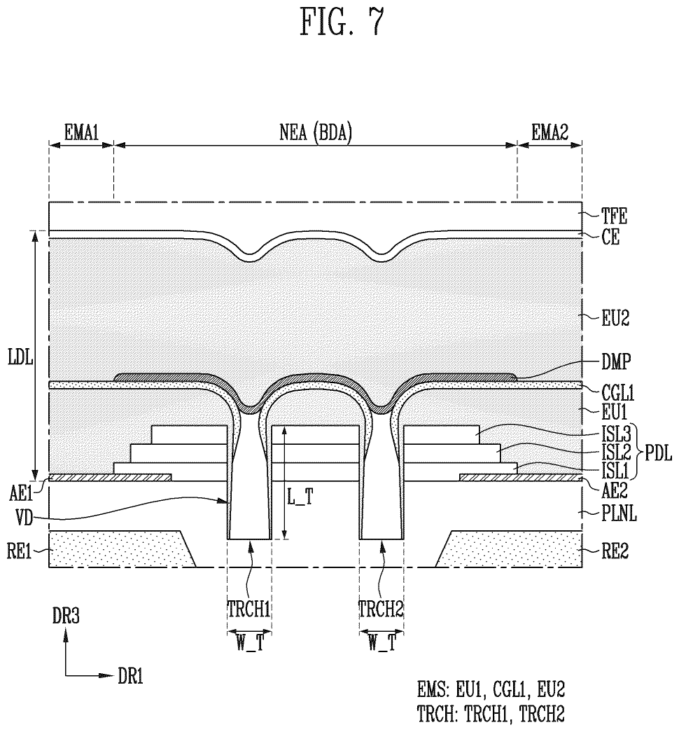

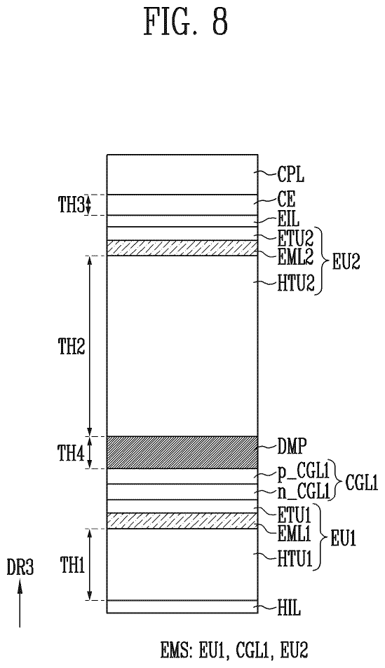

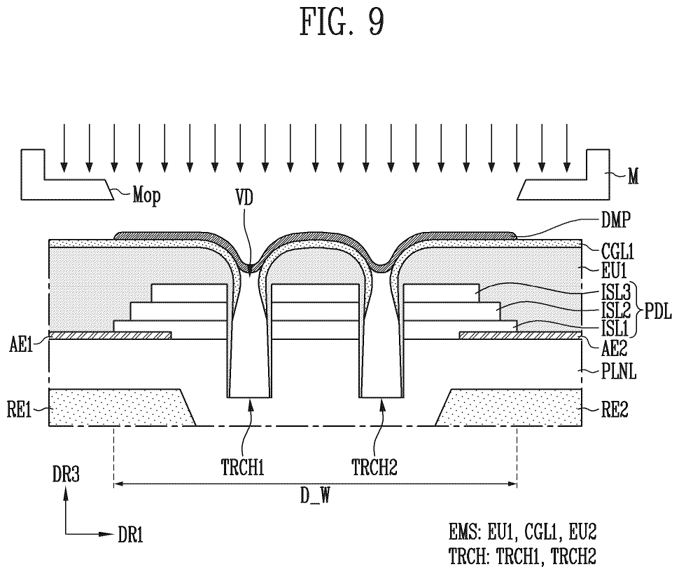

FIG. 7 is a schematic cross-sectional view of an enlarged part of the display device 100 of FIG. 1, according to one or more embodiments of the present disclosure. FIG. 8 is a schematic cross-sectional view illustrating a part of a light-emitting element layer LDL included in the display device 100 of FIG. 7, according to one or more embodiments of the present disclosure. FIG. 9 is a schematic cross-sectional view illustrating a method of forming a dummy pattern DMP of FIG. 7, according to one or more embodiments of the present disclosure.

FIG. 7 depicts a light-emitting element layer LDL in a partial area (e.g., the boundary area BDA between the first sub-pixel SP1 (see, e.g., FIG. 2) and the second sub-pixel SP2 (see, e.g., FIG. 2)) including first and second trenches TRCH1 and TRCH2, and a light-emitting element layer LDL in each of a first emission area EMA1 and a second emission area EMA2 adjacent to the partial area. Also, FIG. 7 further depicts a planarization layer PLNL and an encapsulation layer TFE for clarity.

In FIG. 7 to FIG. 9, explanation focuses on differences from the above embodiments to avoid redundant explanation.

Referring to FIG. 2, and FIG. 7 to FIG. 9, the pixel-defining layer PDL may be arranged on the planarization layer PLNL.

The pixel-defining layer PDL may include, but not limited to, a first inorganic insulation layer ISL1, a second inorganic insulation layer ISL2, and a third inorganic insulation layer ISL3 which are sequentially stacked along the third direction DR3 (e.g., in a plan view). According to one or more embodiments, the pixel-defining layer PDL may further include additional inorganic insulation layers in addition to the inorganic insulation layers mentioned above.

The first inorganic insulation layer ISL1 and the third inorganic insulation layer ISL3 may include silicon nitride, and the second inorganic insulation layer ISL2 may include silicon oxide. However, the material of the first to third inorganic insulation layers ISL1 to ISL3 is not limited to one or more embodiments described above. An area adjacent to the first opening OP1 (see, e.g., FIG. 2) of the pixel-defining layer PDL including the first to third inorganic insulation layers ISL1 to ISL3 may have a stepped cross-section, but the present disclosure is not limited thereto. The thickness of each of the first inorganic insulation layer ISL1 and the third inorganic insulation layer ISL3 may be about 500 Å, and the thickness of the second inorganic insulation layer ISL2 may be about 150 Å, but the present disclosure is not limited thereto.

Trenches TRCH may be positioned between the first sub-pixel SP1 and the second sub-pixel SP2. For example, the first trench TRCH1 and the second trench TRCH2 may be positioned in the non-emission area NEA (or the boundary area BDA) between the first sub-pixel SP1 and the second sub-pixel SP2.

Each of the first and second trenches TRCH1 and TRCH2 may include or may be defined (or formed) by a portion penetrating the pixel-defining layer PDL and a recessed portion pentrating at least a part of the planarization layer PLNL. The first and second trenches TRCH1 and TRCH2 each may be arranged in the boundary area BDA between the first sub-pixel SP1 and the second sub-pixel SP2 to be around (e.g., surround) the first emission area EMA1 of the first sub-pixel SP1 and the second emission area EMA2 of the second sub-pixel SP2, but the present disclosure is not limited thereto. A width W_T of each of the first and second trenches TRCH1 and TRCH2 may range from about 900 Å to about 1100 Å, but the present disclosure is not limited thereto. A depth L_T of each of the first and second trenches TRCH1 and TRCH2 may range from about 2,700 Å to about 3,300 Å, but the present disclosure is not limited thereto. The depth L_T and the width W_T of each trench TRCH, and the thickness of the first and second emission components EU1 and EU2 may be set by considering the disconnection of the first intermediate layer CGL1 and the connection (and the resonance distance) of the cathode electrode CE.

The emission structure EMS may be arranged on the first anode electrode AE1, the pixel-defining layer PDL, and the second anode electrode AE2 in the first emission area EMA1, the boundary area BDA (or the non-emission area NEA), and the second emission area EMA2, respectively. The emission structure EMS may include the first emission component EU1 and the second emission component EU2. The emission structure EMS may be configured substantially identically to each of the first, second, and third light-emitting elements LD1, LD2, and LD3 described in reference to FIG. 4, but the present disclosure is not limited thereto. In one or more embodiments, the emission structure EMS may be formed using a vacuum deposition scheme.

Each of the first and second emission components EU1 and EU2 may include an emission layer for producing light according to the applied current. The first emission component EU1 may include a first emission layer EML1, a first hole transporter HTU1, and a first electron transporter ETU1. The first emission layer EML1 may be arranged between the first hole transporter HTU1 and the first electron transporter ETU1. The second emission component EU2 may include a second emission layer EML2, a second hole transporter HTU2, and a second electron transporter ETU2. The second emission layer EML2 may be arranged between the second hole transporter HTU2 and the second electron transporter ETU2.

According to one or more embodiments, the emission structure EMS may further include a hole injection layer HIL and an electron injection layer EIL (see, e.g., FIG. 8). The hole injection layer HIL may be arranged between each of the first and second anode electrodes AE1 and AE2 and the first emission component EU1, and the electron injection layer EIL may be arranged between the cathode electrode CE and the second emission component EU2. The hole injection layer HIL may lower an injection barrier between each of the first and second anode electrodes AE1 and AE2 and the first hole transporter HTU1 of the first emission component EU1. The hole injection layer HIL may include, but is not limited to, a hole injection material and a p-type (kind) dopant. The electron injection layer EIL may lower an injection barrier between the cathode electrode CE and the second electron transporter ETU2 of the second emission component EU2. The electron injection layer EIL may include, but is not limited to, an electron injection material and an n-type (kind) dopant.

In one or more embodiments, the first emission layer EML1 and the second emission layer EML2 may produce light of different colors. The light emitted from each of the first emission layer EML1 and the second emitting layer EML2 may be mixed and recognized as white light. For example, the first emission layer EML1 may produce blue-colored light, and the second emission layer EML2 may produce yellow-colored light. In one or more embodiments, the second emission layer EML2 may include a structure in which a first sub-emission layer configured to produce red-colored light and a second sub-emission layer configured to produce green-colored light are stacked. The red-colored light and the green-colored light may be mixed to provide yellow light. In such embodiments, a layer for transporting holes and/or having a function for blocking the transport of electrons may be further arranged between the first and second sub-emission layers.

The emission structure EMS may further include a first intermediate layer CGL1. The first intermediate layer CGL1 (or a first charge generation layer) may be arranged between the first emission component EU1 and the second emission component EU2. The first intermediate layer CGL1 may generate an electric charge. The first intermediate layer CGL1 may interconnect the first emission component EU1 and the second emission component EU2. The first intermediate layer CGL1 may be conductive (e.g., may include a conductor) by including a material of relatively higher charge conductivity (or charge mobility) than the first and second emission components EU1 and EU2.

The first intermediate layer CGL1 may include an n-type (kind) charge generation layer n_CGL1 and a p-type (kind) charge generation layer p_CGL1 sequentially stacked. In at least the emission areas EMA1 and EMA2, the n-type (kind) charge generation layer n_CGL1 may provide electrons to the first electron transporter ETU1 of the first emission component EU1, and the p-type (kind) charge generation layer p_CGL1 may provide holes to the second hole transporter HTU2 of the second emission component EU2.

In one or more embodiments, in the third direction DR3, a thickness TH1 of the first hole transporter HTU1 may be smaller than the depth L_T of the trench TRCH, and a thickness TH2 of the second hole transporter HTU2 may be greater than the depth L_T of the trench TRCH. In one or more embodiments, if the depth L_T of the trench TRCH is about 3,000 Å and the width W_T of the trench TRCH ranges from about 900 Å to about 1,100 Å, the thickness TH1 of the first hole transporter HTU1 may fall within a range from about 1,200 Å to about 1,650 Å, and the thickness TH2 of the second hole transporter HTU2 may fall within a range from about 3,600 Å to about 4,400 Å, but the present disclosure is not limited thereto.

If the thickness TH1 of the first hole transporter HTU1 is smaller than the depth L_T of the trench TRCH, the first intermediate layer CGL1 and the first emission component EU1 may be disconnected more stably above the trench TRCH. If the thickness TH2 of the second hole transporter HTU2 is greater than the depth L_T of the trench TRCH, the second emission component EU2 and the cathode electrode CE may be connected more stably above the trench TRCH. In one or more embodiments, the second hole transporter HTU2 may have a thickness of about half a total thickness of the emission structure EMS. For example, if the emission structure EMS has the thickness of about 6,000 Å, the second hole transporter HTU2 may have the thickness of about 3,000 Å.

The first emission component EU1 and the second emission component EU2 may include a material of relatively lower charge conductivity (or charge mobility) than the first intermediate layer CGL1. In one or more embodiments, the first emission component EU1 and the second emission component EU2 may include a material with relatively greater insulation properties than the first intermediate layer CGL1. In such embodiments, even if the first and second emission components EU1 and EU2 are interconnected on (across) the trench TRCH, no current may be transmitted to adjacent sub-pixels SP.

The first emission component EU1 may be arranged on the pixel-defining layer PDL in the non-emission area NEA (or the boundary area BDA) between the first sub-pixel SP1 and the second sub-pixel SP2. In one or more embodiments, the first emission component EU1 may be arranged on the first anode electrode AE1 in the first emission area EMA1, and may be arranged on the second anode electrode AE2 in the second emission area EMA2. The first emission component EU1 may include a disconnecting portion (or an opening portion) separating the first emission component EU1 within the trench TRCH positioned in the non-emission area NEA, for example, the boundary area BDA between adjacent sub-pixels SP. The disconnecting portion may be defined as a portion in which the first emission component EU1 is disconnected, without being formed continuously within the trench TRCH. In such embodiments, the first emission component EU1 of the adjacent sub-pixels SP may be separated from each other. For example, the first emission component EU1 at the first sub-pixel SP1 and the first emission component EU1 at the second sub-pixel SP2 may be separated from each other.

The first intermediate layer CGL1 may be arranged on the first emission component EU1. The first intermediate layer CGL1 may include a disconnecting portion separating the first intermediate layer CGL1 within the trench TRCH. In such embodiments, the first intermediate layer CGL1 of adjacent sub-pixels SP may be separated from each other. For example, the first intermediate layer CGL1 at the first sub-pixel SP1 and the first intermediate layer CGL1 at the second sub-pixel SP2 may be separated from each other.

The second emission component EU2 may be arranged on the first intermediate layer CGL1. The second emission component EU2 may be formed on the first intermediate layer CGL1 to have a relatively thick thickness. Hence, the second emission component EU2 may not be disconnected in the boundary area BDA between adjacent sub-pixels SP. For example, the second emission component EU2 at the first sub-pixel SP1 and the second emission component EU2 at the second sub-pixel SP2 may be connected to each other. According to one or more embodiments, at least a part of the second emission component EU2 of one of two adjacent sub-pixels SP and at least a part of the second emission component EU2 of the other sub-pixel may be disconnected on the trench TRCH. For example, a bottom surface (e.g., a surface contacting the first intermediate layer CGL1) of the second emission component EU2 at the adjacent sub-pixels SP may be disconnected at the trench TRCH, and a top surface (e.g., a surface contacting the cathode electrode CE) facing (e.g., opposite to) the bottom surface in the third direction DR3 may be connected (e.g., continuous). Hence, the second emission component EU2 may not be disconnected on the trench TRCH.

As described above, the first intermediate layer CGL1 may be disconnected at/above the trench TRCH. In such embodiments, current leakage from one sub-pixel SP to another neighboring sub-pixel SP through the first intermediate layer CGL1 may be reduced or prevented, and each sub-pixel SP may operate with high reliability. In addition, if the first intermediate layer CGL1 each is disconnected at/above the trench TRCH, color mixing between adjacent sub-pixels SP may be prevented or reduced to allow each sub-pixel SP to emit light of the intended color.

The cathode electrode CE may be arranged on the second emission component EU2. The cathode electrode CE may include metal including a conductive material. The second emission component EU2 arranged below the cathode electrode CE may be formed to have a relatively thicker thickness than the first emission component EU1. The thickness of the second emission component EU2 may provide (or create) a gap or distance between the first intermediate layer CGL1 and the cathode electrode CE in the third direction DR3. For example, the thickness of the second emission component EU2, corresponding to the gap/distance between the first intermediate layer CGL1 and the cathode electrode CE may be greater than the thickness of the first emission component EU1. This is to prevent or reduce the likelihood of a defect which may occur if the cathode electrode CE is short-circuited with the first intermediate layer CGL1, which includes a material having high charge conductivity (or charge mobility), and to prevent or reduce the likelihood of the cathode electrode CE from being disconnected due to the configuration/layers (e.g., the first intermediate layer CGL1 and the first emission component EU1) positioned below the cathode electrode CE. Due to the thicker thickness of the second emission component EU2, the gap between the cathode electrode CE and the first intermediate layer CGL1 may be further secured to prevent or reduce the likelihood of a defect if the cathode electrode CE and the first intermediate layer CGL1 connect and are short-circuited. In one or more embodiments, due to the second emission component EU2, the steps caused by the configurations positioned there below may be smoothed to improve step coverage of the cathode electrode CE arranged on the second emission component EU2 and to prevent or reduce the likelihood of a failure resulting from a disconnection of the cathode electrode CE on/at the trench TRCH.

In one or more embodiments, a thickness TH3 of the cathode electrode CE may range from about 100 Å to about 190 Å, or range from about 150 Å to about 185 Å, but the present disclosure is not limited thereto. As the thickness TH3 of the cathode electrode CE increases, the cathode electrode CE may be connected more stably in the trench TRCH, but light transmission efficiency of the cathode electrode CE may be lowered.

A capping layer CPL including an inorganic material may be arranged on the cathode electrode CE to protect the cathode electrode CE.

In one or more embodiments, as shown, e.g., in FIG. 9, the dummy pattern DMP may be arranged in the non-emission area NEA between adjacent sub-pixels SP, for example, in the non-emission area NEA (or the boundary area BDA) between the first sub-pixel SP1 and the second sub-pixel SP2. The dummy pattern DMP may not be disconnected on the trench TRCH. For example, the dummy pattern DMP may be connected without being disconnected in the boundary area BDA between adjacent sub-pixels SP.

The dummy pattern DMP may be arranged between the first intermediate layer CGL1 and the cathode electrode CE. For example, the dummy pattern DMP may be arranged between the first intermediate layer CGL1 and the second emission component EU2. The dummy pattern DMP may be arranged between the first intermediate layer CGL1 and the second hole transporter HTU2 of the second emission component EU2. A thickness TH4 of the dummy pattern DMP may range from 100 Å to 3,000 Å, but the present disclosure is not limited thereto. The thickness TH4 of the dummy pattern DMP may be greater than or equal to the thickness TH3 of the cathode electrode CE and smaller than the thickness TH2 of the second hole transporter HTU2.

The dummy pattern DMP may be arranged on the first intermediate layer CGL1 to correspond to the pixel-defining layer PDL. The dummy pattern DMP may include a material of greater resistance than the first emission component EU1 and the second emission component EU2. In such embodiments, the dummy pattern DMP may have insulation properties. In one or more embodiments, the dummy pattern DMP may be an organic insulation pattern including an organic material (or substance). For example, the organic material (or substance) may include, but is not limited to, parylene. According to one or more embodiments, the organic material may include at least one of polyacrylate, epoxy, polyurethane, and/or polysiloxane.

The dummy pattern DMP may improve electrical insulation properties in the boundary area BDA between adjacent sub-pixels SP and thus block or reduce lateral leakage which may be transmitted upwards through the first intermediate layer CGL1 positioned below the dummy pattern DMP.

The dummy pattern DMP may be arranged on the first intermediate layer CGL1 using a vacuum deposition method and/or the like. For example, the dummy pattern DMP may be formed by depositing a deposition material corresponding to a base material of the dummy pattern DMP on a target substrate within a deposition chamber which provides a sealed space maintained in a reduced pressure atmosphere. The deposition material may include an organic material configured with parylene. As shown in FIG. 9, a mask M including a mask opening Mop may be arranged above the target substrate where the first intermediate layer CGL1 is formed, and the deposition material may be sprayed from a deposition source positioned above the mask M and deposited on the first intermediate layer CGL1 through the mask opening Mop in the deposition chamber. The deposition material deposited on the first intermediate layer CGL1 may finally form the dummy pattern DMP. The mask opening Mop may correspond to an area for forming the dummy pattern DMP. A width D_W of the dummy pattern DMP may be, for example, about 1.5 μm, but the present disclosure is not limited thereto. After forming the dummy pattern DMP, the second emission component EU2 may be formed. The mask M in the deposition chamber may be, but is not limited to, a wafer mask. According to one or more embodiments, the mask M may be a fine metal mask.

In one or more embodiments, a void VD may be formed within the trench TRCH. The void VD may be surrounded by some configuration of the emission structure EMS disconnected in the trench TRCH, the dummy pattern DMP, and the planarization layer PLNL. For example, the void VD may be surrounded by, but is not limited to being surrounded by, the planarization layer PLNL, the first emission component EU1, the first intermediate layer CGL1, and/or the dummy pattern DMP in each of the first and second trenches TRCH1 and TRCH2. In one or more embodiments, the planarization layer PLNL, the first emission component EU1, the first intermediate layer CGL1, and/or the dummy pattern DMP may be around or partially around the void VD in each of the first and second trenches TRCH1 and TRCH2.

As high resolution, high brightness, and high definition are desired or required for the display device 100 (see, e.g., FIG. 1), the gap between adjacent sub-pixels SP may be narrowed and the display device 100 may be vulnerable to lateral leakage. As the pixel-defining layer PDL has the multi-layer structure including the first to third inorganic insulation layers ISL1 to ISL3, a side (or an end) of the pixel-defining layer PDL adjacent to the first opening OP1 (see, e.g., FIG. 4) exposing each of the first and second anode electrodes AE1 and AE2 may have a stepped cross-section. In such embodiments, the current may be concentrated on the side (or the end) of the stepped shape of the pixel-defining layer PDL adjacent to each of the first and second anode electrodes AE1 and AE2. As a result, some current may move to the boundary area BDA (e.g., the non-emission area NEA) between the first sub-pixel SP1 and the second sub-pixel SP2 and leak upwards through the configurations positioned in the boundary area BDA. If the current leaks into the boundary area BDA between the first sub-pixel SP1 and the second sub-pixel SP2, the luminance of the light emitted by the first and second sub-pixels SP1 and SP2 may be lowered and the emission efficiency may be reduced.

In the above embodiments, by disposing the dummy pattern DMP directly on the first intermediate layer CGL1 in the non-emission area NEA (or the boundary area BDA) between the first sub-pixel SP1 and the second sub-pixel SP2, it is possible to block or reduce the likelihood of the current flowing upwards through the first emission component EU1 and the first intermediate layer CGL1 even if the current is concentrated on the side (or the end) of the pixel-defining layer PDL adjacent to the first and second anode electrodes AE1 and AE2 and some current leaks into the non-emission area NEA.

The dummy pattern DMP may restrict the current to flow only upwards in the first opening OP1 of the pixel-defining layer PDL corresponding to each of the first and second emission areas EMA1 and EMA2, and thus the light may be emitted only in the emission area of each sub-pixel SP as intended.

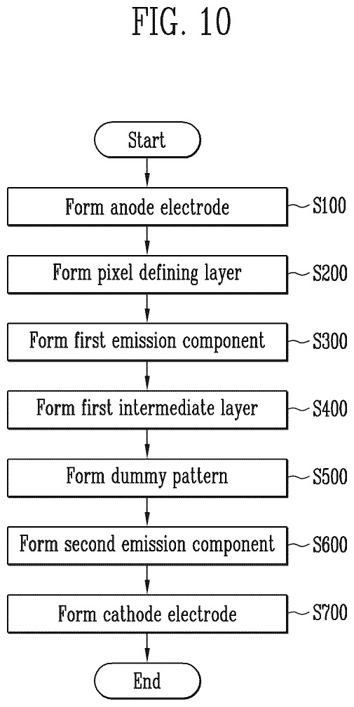

FIG. 10 is a flowchart illustrating a manufacturing method of a display device 100 according to one or more embodiments of the present disclosure.

In FIG. 10, descriptions that are redundant with the above embodiments may not be provided for the sake of the clarity of explanation and to avoid unnecessary repetition.

Referring to FIG. 10, an anode electrode is formed on the planarization layer PLNL (see, e.g., FIG. 7) (S100).

For example, a first anode electrode AE1 (see, e.g., FIG. 7), a second anode electrode AE2 (see, e.g., FIG. 7), and a third anode electrode AE3 (see, e.g., FIG. 4) spaced and/or apart (e.g., spaced apart or separated) from each other may be formed on the planarization layer PLNL.

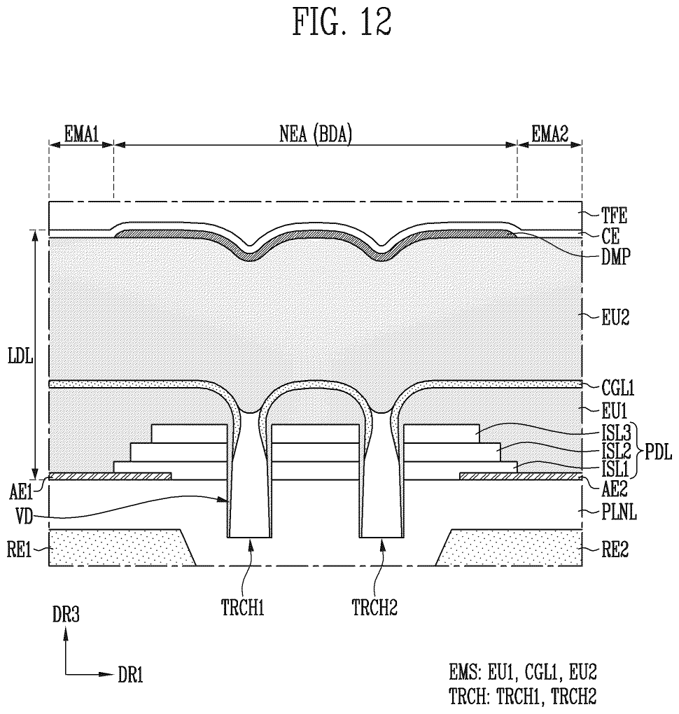

A pixel-defining layer PDL (see, e.g., FIG. 12) is formed on the first to third anode electrodes AE1 to AE3 (S200).

For example, the pixel-defining layer PDL may be formed entirely on (e.g., formed across an entirety of) the first anode electrode AE1, the second anode electrode AE2, the third anode electrode AE3, and the planarization layer PLNL. The pixel-defining layer PDL may include a first opening OP1 (see, e.g., FIG. 4) exposing the anode electrode in the emission area of each sub-pixel SP. A non-emission area NEA (see, e.g., FIG. 7) (or a boundary area BDA (see, e.g., FIG. 7)) between adjacent sub-pixels SP may be provided with a trench TRCH (see, e.g., FIG. 7) formed by penetrating the pixel-defining layer PDL and recessing at least a part of the planarization layer PLNL.

A first emission component EU1 (see, e.g., FIG. 7) is formed on the pixel-defining layer PDL using the vacuum deposition method and/or the like (S300).

The first emission component EU1 may be disconnected on the trench TRCH. The first emission component EU1 may include a first hole transporter HTU1 (see, e.g., FIG. 8), a first emission layer EML1 (see, e.g., FIG. 8), and a first electron transporter ETU1 (see, e.g., FIG. 8).

A first intermediate layer CGL1 (see, e.g., FIG. 7) is formed on the first emission component EU1 using the vacuum deposition method and/or the like (S400).

The first intermediate layer CGL1 may be disconnected in a trench TRCH in substantially the same manner as the first emission component EU1.

A dummy pattern DMP (see, e.g., FIG. 7) is formed on the first intermediate layer CGL1 in the non-emission area NEA (or the boundary area BDA) between adjacent sub-pixels SP (S500).

The dummy pattern DMP may be formed on the first intermediate layer CGL1 to correspond to the pixel-defining layer PDL positioned in the non-emission area NEA between adjacent sub-pixels SP using the vacuum deposition method and/or the like. The dummy pattern DMP may be connected on the trench TRCH without being disconnected.

A second emission component EU2 (see, e.g., FIG. 7) is formed on the dummy pattern DMP (S600).

The second emission component EU2 may be arranged on the dummy pattern DMP and the first intermediate layer CGL1. The second emission component EU2 may not be disconnected on the trench TRCH. The second emission component EU2 may include a second hole transporter HTU2 (see, e.g., FIG. 8), a second emission layer EML2 (see, e.g., FIG. 8), and a second electron transporter ETU2 (see, e.g., FIG. 8).

The cathode electrode CE (see, e.g., FIG. 7) is formed on the second emission component EU2 (S700).

For example, the cathode electrode CE may be a common layer provided in (across) the adjacent sub-pixels SP.

Next, as shown in FIG. 4, for example, the encapsulation layer TFE, the optical functional layer OFL, the overcoat layer OC, and the cover window CW, and/or the like may be formed sequentially. Thus, the display device 100 according to one or more embodiments of FIG. 4 may be manufactured.

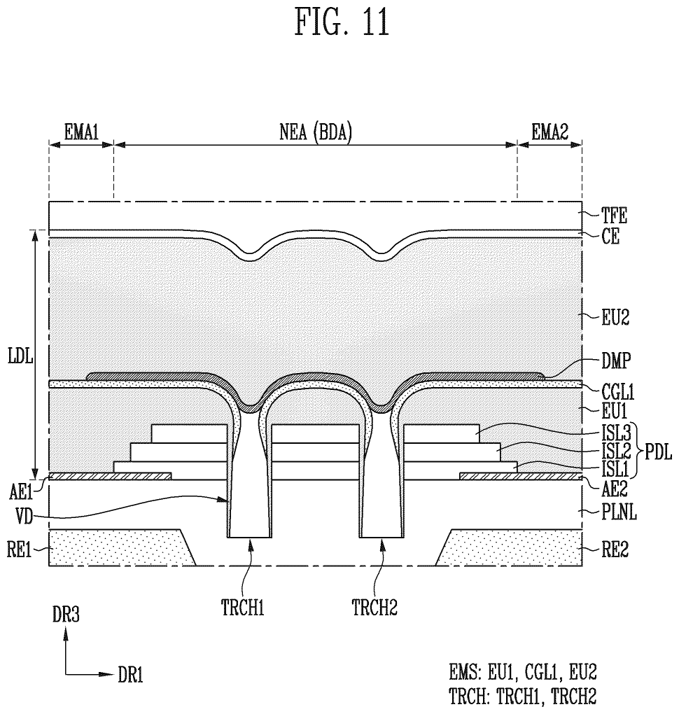

FIG. 11 to FIG. 14 are schematic cross-sectional views of an enlarged portion of the display device 100 of FIG. 1, according to one or more embodiments of the present disclosure. FIG. 11 to FIG. 14 depict a light-emitting element layer LDL in a partial area (e.g., a boundary area BDA between a first sub-pixel SP1 (see, e.g., FIG. 2) and a second sub-pixel SP2 (see, e.g., FIG. 2)) including first and second trenches TRCH1 and TRCH2, and the light-emitting element layer LDL in each of a first emission area EMA1 and a second emission area EMA2 adjacent to the partial area.

In FIG. 11 to FIG. 14, descriptions focus on differences from the above embodiments to avoid redundant explanations.

Referring to FIG. 2 and FIG. 11, the dummy pattern DMP may be arranged between the first intermediate layer CGL1 and the second emission component EU2 in the non-emission area NEA (or the boundary area BDA) between adjacent sub-pixels SP. In one or more embodiments, the dummy pattern DMP may be arranged between the first intermediate layer CGL1 and the second emission component EU2 in one area of the first emission area EMA1 of the first sub-pixel SP1 (see, e.g., FIG. 2) adjacent to the non-emission area NEA. In one or more embodiments, the dummy pattern DMP may be arranged between the first intermediate layer CGL1 and the second emission component EU2 in one area of the second emission area EMA2 of the second sub-pixel SP2 (see, e.g., FIG. 2) adjacent to the non-emission area NEA.

The dummy pattern DMP may be arranged on the first intermediate layer CGL1 to extend up to not only the edge (or end) of the non-emission area NEA between the sub-pixels SP but also may cover a part of an emission area (e.g., each of the first and second emission areas EMA1 and EMA2) adjacent to the non-emission area NEA so as to more completely cover the side (or the end) of the pixel-defining layer PDL adjacent to each of the first and second anode electrodes AE1 and AE2. When viewed in a cross-section (e.g., in the first and/or second direction DR1 and/or DR2), the end of the dummy pattern DMP may be positioned outward relative to one end of the first inorganic insulation layer ISL1 (e.g., the end closer to the anode electrode than the second and third inorganic insulation layers ISL2 and ISL3), and may thus extend into the first and/or second emission areas EMA1 and/or EMA2.

Referring to FIG. 2 and FIG. 12, the dummy pattern DMP may be arranged between the second emission component EU2 and the cathode electrode CE in the non-emission area NEA (or the boundary area BDA) between adjacent sub-pixels SP. For example, the dummy pattern DMP may be arranged directly below the cathode electrode CE in the non-emission area NEA between the adjacent sub-pixels SP. In such embodiments, the dummy pattern DMP may be formed on the second emission component EU2 with the thickness enough not to disconnect the cathode electrode CE. The dummy pattern DMP may be an organic insulation pattern including an organic material of greater resistance than the first emission component EU1 and the second emission component EU2.

The dummy pattern DMP arranged below the cathode electrode CE may block or reduce the likelihood of lateral leakage generated in the non-emission area NEA between the adjacent sub-pixels SP from being transmitted to the cathode electrode CE through the first emission component EU1, the first intermediate layer CGL1, and the second emission component EU2, such that the lateral leakage does not affect or has a reduced effect on a voltage applied to the cathode electrode CE.

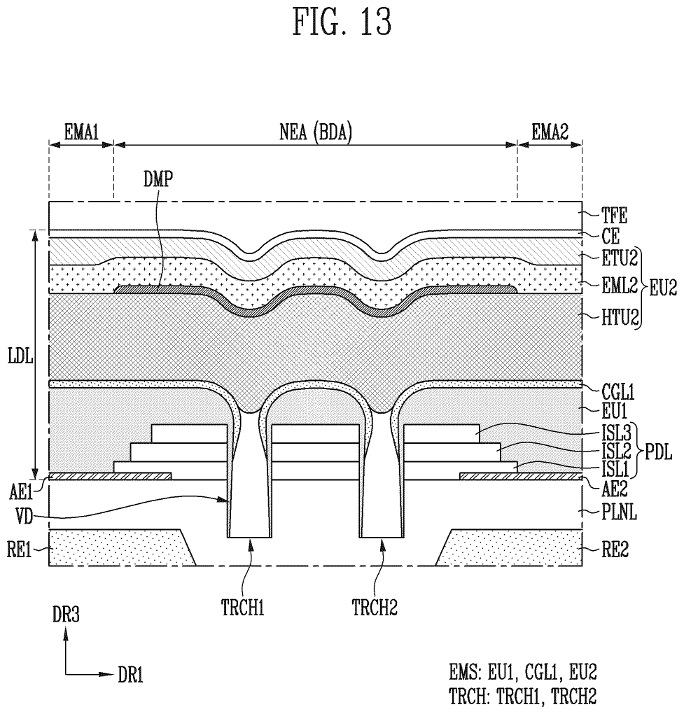

Referring to FIG. 2 and FIG. 13, the dummy pattern DMP may be arranged between some layers of the second emission component EU2 in the non-emission area NEA (or the boundary area BDA) between the adjacent sub-pixels SP. For example, the dummy pattern DMP may be arranged between the second hole transporter HTU2 and the second emission layer EML2 in the non-emission area NEA between the adjacent sub-pixels SP. The dummy pattern DMP arranged on the second hole transporter HTU2 may be utilized as a member for improving the electrical insulation properties in the non-emission area NEA by blocking some of the current from moving from the non-emission area NEA in the third direction DR3 (or the vertical direction) due to the current concentrated on the side (or the end) of the pixel-defining layer PDL.

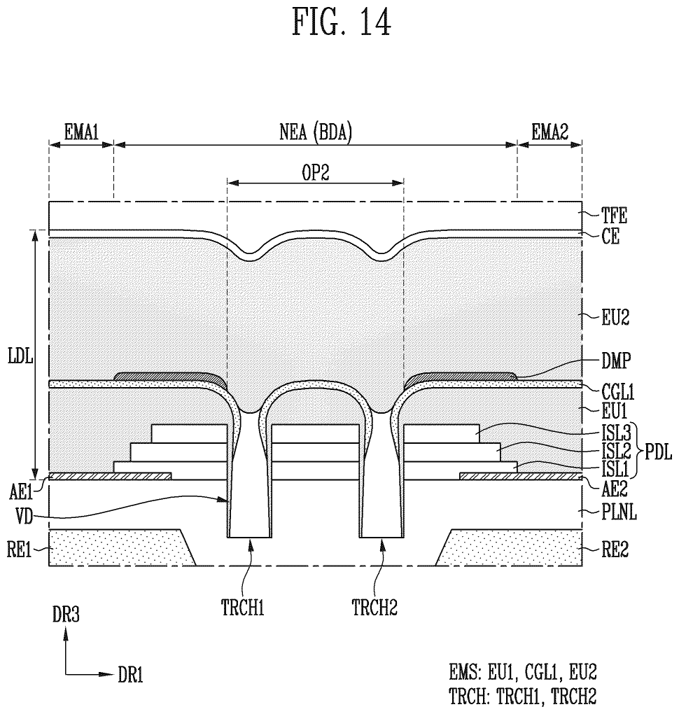

Referring to FIG. 2 and FIG. 14, the dummy pattern DMP may be arranged between the first intermediate layer CGL1 and the second emission component EU2 in the non-emission area NEA (or the boundary area BDA) between the adjacent sub-pixels SP. The dummy pattern DMP may not be arranged on the trench TRCH. Hence, the dummy pattern DMP may not overlap the trench TRCH. The dummy pattern DMP may include a second opening OP2 for exposing the emission structure EMS arranged on the trench TRCH. For example, the dummy pattern DMP may include the second opening OP2 exposing the first emission component EU1 and the first intermediate layer CGL1 arranged on the trench TRCH.

In one or more embodiments, the dummy pattern DMP may not be arranged on the first and second trenches TRCH1 and TRCH2 in order to not affect the first and second trenches TRCH1 and TRCH2 functioning as the separator SPR (see, e.g., FIG. 4) which forms the discontinuous portion in the emission structure EMS in the boundary area BDA between the neighboring sub-pixels SP, and may be arranged only on, but is not limited to being arranged only on, the first intermediate layer CGL1 on the pixel-defining layer PDL adjacent to the first and second anode electrodes AE1 and AE2.

The void VD of each trench TRCH may be surrounded by, but is not limited to being surrounded by, the planarization layer PLNL, the first emission component EU1, the first intermediate layer CGL1, and/or the second emission component EU2.

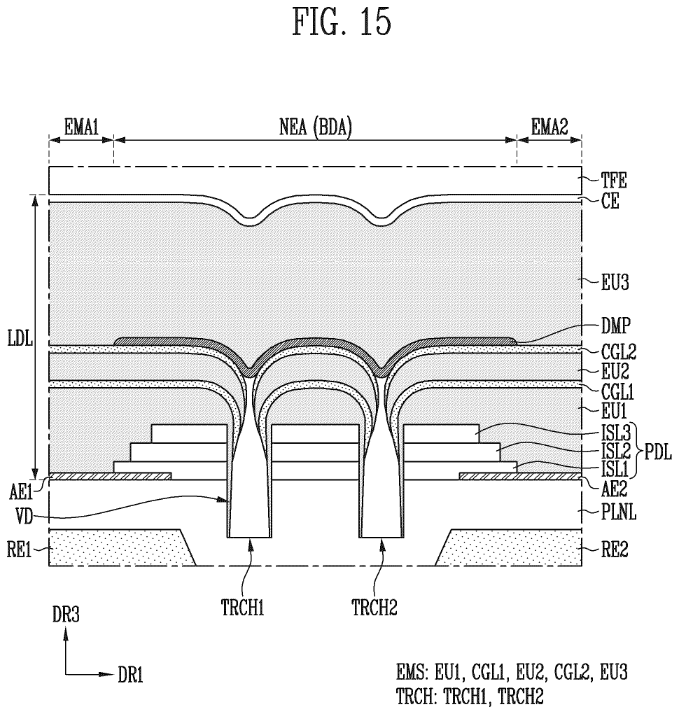

FIG. 15 to FIG. 19 are schematic cross-sectional views of an enlarged portion of the display device 100 of FIG. 1, according to one or more embodiments of the present disclosure. FIG. 15 to FIG. 19 depict a light-emitting element layer LDL in a partial area (e.g., a boundary area BDA between a first sub-pixel SP1 (see, e.g., FIG. 2) and a second sub-pixel SP2 (see, e.g., FIG. 2)) including first and second trenches TRCH1 and TRCH2, and the light-emitting element layer LDL in each of a first emission area EMA1 and a second emission area EMA2 adjacent to the partial area.

In FIG. 15 to FIG. 19, descriptions focus on differences from the above embodiments to avoid redundant explanations.

Referring to FIG. 2 and FIG. 15, the emission structure EMS may be arranged on the first and second anode electrodes AE1 and AE2, and the pixel-defining layer PDL.

The emission structure EMS may include the first emission component EU1, the second emission component EU2, and the third emission component EU3. The emission structure EMS may be configured substantially identically to each of the first, second, and third light-emitting elements LD1, LD2, and LD3 described in reference to FIG. 4, but the present disclosure is not limited thereto. The emission structure EMS may further include the first intermediate layer CGL1 and the second intermediate layer CGL2. The first intermediate layer CGL1 (or the first charge generation layer) may be arranged between the first emission component EU1 and the second emission component EU2, and the second intermediate layer CGL2 (or the second charge generation layer) may be arranged between the second emission component EU2 and the third emission component EU3.

Each of the first emission component EU1, the second emission component EU2, and the third emission component EU3 may include an emission layer for producing light according to the applied current. The first emission component EU1 may be the same as the first emission component EU1′ described in reference to FIG. 6, the second emission component EU2 may be the same as the second emission component EU2′ described in reference to FIG. 6, and the third emission component EU3 may be the same as the third emission component EU3′ described in reference to FIG. 6.

The first, second, and third emission components EU1, EU2, and EU3 may include the hole transporter, the emission layer, the electron transporter, the buffer layer and/or the like including a material with a relatively lower charge conductivity (or charge mobility) than the first and second intermediate layers CGL1 and CGL2. The first, second, and third emission components EU1, EU2, and EU3 may include a material of relatively greater insulation properties than the first and second intermediate layers CGL1 and CGL2. In such embodiments, even if the first, second, and third emission components EU1, EU2, and EU3 are connected to each other on (at) the trench TRCH, no current may be transmitted to the adjacent sub-pixels SP.

The first emission component EU1 and the second emission component EU2 may include the disconnecting portion (or an opening portion) separating the first emission component EU1 within the first and second trenches TRCH1 and TRCH2. The disconnecting portion may be defined as a portion where each of the first and second emission components EU1 and EU2 is not formed continuously but is disconnected in the first and second trenches TRCH1 and TRCH2. In such embodiments, the first emission component EU1 at the first sub-pixel SP1 may be separated from the first emission component EU1 at the second sub-pixel SP2, and the second emission component EU2 at the first sub-pixel SP1 may be separated from the second emission component EU2 at the second sub-pixel SP2.

In one or more embodiments, at least a part of the third emission component EU3 at the first sub-pixel SP1 and at least a part of the third emission component EU3 at the second sub-pixel SP2 may be disconnected within the first and second trenches TRCH1 and TRCH2. For example, the bottom surface (e.g., one surface contacting the second intermediate layer CGL2) of the third emission component EU3 of the adjacent sub-pixels SP may be disconnected within the first and second trenches TRCH1 and TRCH2 and the top surface (e.g., one surface contacting the cathode electrode CE) facing (e.g., opposite to) the bottom surface in the third direction DR3 may be connected (e.g., continuous). In such embodiments, the third emission component EU3 at the first sub-pixel SP1 and the third emission component EU3 at the second sub-pixel SP2 may be connected.

The first intermediate layer CGL1 and the second intermediate layer CGL2 may each generate an electric charge. The first intermediate layer CGL1 may interconnect the first emission component EU1 and the second emission component EU2, and the second intermediate layer CGL2 may interconnect the second emission component EU2 and the third emission component EU3. The first and second intermediate layers CGL1 and CGL2 may be conductive by including a material with relatively high charge conductivity (or charge mobility) compared to the first, second, and third emission components EU1, EU2, and EU3.

Each of the first and second intermediate layers CGL1 and CGL2 may include a disconnecting portion (or an opening portion) separating the first and second intermediate layers CGL1 and CGL2 within (or on) the first and second trenches TRCH1 and TRCH2 in a similar manner to the first and second emission components EU1 and EU2. The disconnecting portion may be defined as a portion where each of the first and second intermediate layers CGL1 and CGL2 are not formed continuously but are disconnected within the first and second trenches TRCH1 and TRCH2. For example, the first and second intermediate layers CGL1 and CGL2 may be disconnected above (at) the first and second trenches TRCH1 and TRCH2, respectively. In such embodiments, the leakage of current from one sub-pixel SP to a neighboring sub-pixel SP through the first and second intermediate layers CGL1 and CGL2 may be reduced or prevented, and the sub-pixel SP may operate with high reliability. In addition, if the first and second intermediate layers CGL1 and CGL2 are disconnected above (at) the first and second trenches TRCH1 and TRCH2, respectively, color mixing between the adjacent sub-pixels SP may be prevented or reduced and thus each sub-pixel SP may be to emit light of an intended color.

The first emission component EU1 may be arranged on the first and second anode electrodes AE1 and AE2 and the pixel-defining layer PDL, the first intermediate layer CGL1 may be arranged on the first emission component EU1, the second emission component EU2 may be arranged on the first intermediate layer CGL1, the second intermediate layer CGL2 may be arranged on the second emission component EU2, and the third emission component EU3 may be arranged on the second intermediate layer CGL2. The third emission component EU3 may be formed on the second intermediate layer CGL2 to have a relatively thick thickness. Hence, the third emission component EU3 may not be disconnected in the boundary area BDA between the adjacent sub-pixels SP.

The cathode electrode CE may be arranged on the third emission component EU3 of the emission structure EMS. The third emission component EU3 arranged below the cathode electrode CE may be formed to have a relatively thicker thickness than the first and second emission components EU1 and EU2. The thickness of the third emission component EU3 may provide (or create) the gap or distance between the second intermediate layer CGL2 and the cathode electrode CE. This gap is to prevent or reduce the likelihood of a defect which may occur if the cathode electrode CE is short-circuited with the second intermediate layer CGL2, which includes a material having high charge conductivity (or charge mobility), and to prevent or reduce the likelihood of the cathode electrode CE from being disconnected due to the steps of the layers (e.g., the first and second intermediate layers CGL1 and CGL2 and the first and second emission components EU1 and EU2) positioned below the cathode electrode CE.

The dummy pattern DMP may be arranged in the non-emission area NEA (or the boundary area BDA) between the first sub-pixel SP1 and the second sub-pixel SP2. The dummy pattern DMP may be arranged on the second intermediate layer CGL2 using the vacuum deposition method and so on.

The dummy pattern DMP may not be disconnected on the first and second trenches TRCH1 and TRCH2. For example, the dummy pattern DMP may be connected in the boundary area BDA between the adjacent sub-pixels SP without being disconnected.

The dummy pattern DMP may be arranged between the second intermediate layer CGL2 and the third emission component EU3. The dummy pattern DMP may be arranged between the second intermediate layer CGL2 and the hole transporter of the third emission component EU3. The thickness of the dummy pattern DMP may range from 100 Å to 3,000 Å, but the present disclosure is not limited thereto. The dummy pattern DMP may have a thickness greater than or equal to the thickness of the cathode electrode CE and smaller than the thickness of the hole transporter of the third emission component EU3.

The dummy pattern DMP may be arranged on the second intermediate layer CGL2 to correspond to the pixel-defining layer PDL. According to one or more embodiments, the dummy pattern DMP may be also arranged on the second intermediate layer CGL2 on the pixel-defining layer PDL and the second intermediate layer CGL2 on the first and second anode electrodes AE1 and AE2 adjacent to the pixel-defining layer PDL. The dummy pattern DMP may include a material with greater resistance than the first, second, and third emission components EU1, EU2, and EU3. In such embodiments, the dummy pattern DMP may have insulation properties. In one or more embodiments, the dummy pattern DMP may be an organic insulation pattern including an organic material (or substance). For example, the organic material (or substance) may include, but is not limited to, parylene.

In one or more embodiments, the void VD may be formed in the trench TRCH. The void VD may be surrounded by some configuration of the emission structure EMS disconnected in the trench TRCH, the dummy pattern DMP, and/or the planarization layer PLNL. For example, the void VD may be surrounded by the planarization layer PLNL, the first emission component EU1, the first intermediate layer CGL1, the second emission component EU2, the second intermediate layer CGL2, and the dummy pattern DMP in each of the first and second trenches TRCH1 and TRCH2. For example, the planarization layer PLNL, the first emission component EU1, the first intermediate layer CGL1, the second emission component EU2, the second intermediate layer CGL2, and/or the dummy pattern DMP may be around the void VD in the first and second trenches TRCH1 and TRCH2.

The dummy pattern DMP may improve the electrical insulation properties in the boundary area BDA between the first sub-pixel SP1 and the second sub-pixel SP2, thus blocking the lateral leakage which may be transmitted upwards through the second intermediate layer CGL2 positioned below the dummy pattern DMP.

In the above-described embodiments, by disposing the dummy pattern DMP directly on the second intermediate layer CGL2 in the non-emission area NEA (or the boundary area BDA) between the first sub-pixel SP1 and the second sub-pixel SP2, even if the current is concentrated on the side (or the end) of the pixel-defining layer PDL adjacent to the first and second anode electrodes AE1 and AE2 and some current leaks into the non-emission area NEA, the current may be blocked from flowing upwards through the first emission component EU1, the first intermediate layer CGL1, the second emission component EU2, and the second intermediate layer CGL2. In addition, the dummy pattern DMP may restrict the current to flow only upwards through the first opening OP1 (see, e.g., of FIG. 4) of the pixel-defining layer PDL corresponding to each of the first and second emission areas EMA1 and EMA2, and thus the light may be emitted only in the emission area of each sub-pixel SP as intended. For example, the dummy pattern DMP is placed directly on the second intermediate layer CGL2 in the non-emission area NEA (or boundary area BDA) between the first sub-pixel SP1 and the second sub-pixel SP2. This placement helps block any leaked current from flowing upwards through the emission components and intermediate layers. Additionally, the dummy pattern DMP ensures that current flows only through the first opening OP1 of the pixel-defining layer PDL, corresponding to the emission areas EMA1 and EMA2, thereby ensuring that light is emitted only in the intended emission areas of each sub-pixel SP.

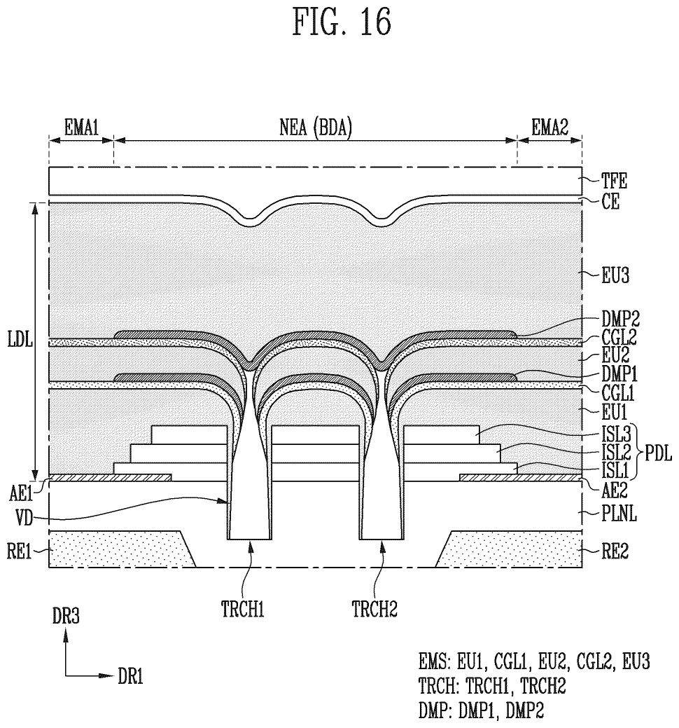

Referring to FIGS. 2 and 16, the dummy pattern DMP may be provided as a plurality of dummy layers. For example, the dummy pattern DMP may include a first dummy pattern DMP1 and a second dummy pattern DMP2 spaced and/or apart (e.g., spaced apart or separated) from each other, and arranged on different layers. The first dummy pattern DMP1 may be arranged between the first intermediate layer CGL1 and the second emission component EU2, and the second dummy pattern DMP2 may be arranged between the second intermediate layer CGL2 and the third emission component EU3. The first dummy pattern DMP1 and the second dummy pattern DMP2 may include the same material. For example, the first dummy pattern DMP1 and the second dummy pattern DMP2 may be organic insulation patterns including an organic material such as parylene.

The first dummy pattern DMP1 may be disconnected on the first and second trenches TRCH1 and TRCH2. The second dummy pattern DMP2 may be connected on the first and second trenches TRCH1 and TRCH2 without being interrupted. For example, the second dummy pattern DMP2 may be connected in the boundary area BDA between the adjacent sub-pixels SP without being disconnected.

The first dummy pattern DMP1 and the second dummy pattern DMP2 may have the same thickness in the third direction DR3, but the present disclosure is not limited thereto. According to one or more embodiments, the second dummy pattern DMP2 may have a thicker thickness than the first dummy pattern DMP1.

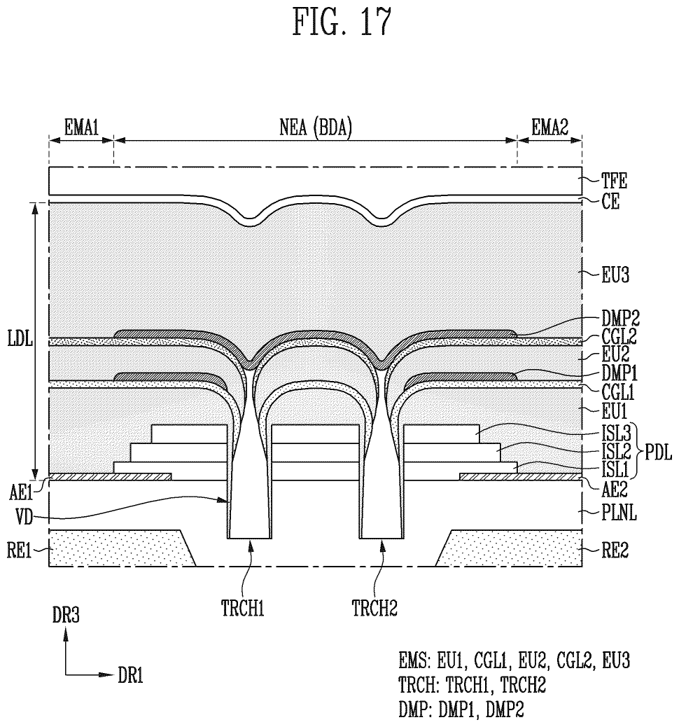

Referring to FIG. 2 and FIG. 17, the dummy pattern DMP may include a first dummy pattern DMP1 arranged between the first intermediate layer CGL1 and the second emission component EU2 and a second dummy pattern DMP2 arranged between the second intermediate layer CGL2 and the third emission component EU3.

The second dummy pattern DMP2 may not be disconnected on the first and second trenches TRCH1 and TRCH2. For example, the second dummy pattern DMP2 may be connected in the boundary area BDA between the adjacent sub-pixels SP without being disconnected.

The first dummy pattern DMP1 may be arranged between the first intermediate layer CGL1 and the second emission component EU2 in the non-emission area NEA (or the boundary area BDA) between the adjacent sub-pixels SP, and may not be arranged on the trench TRCH. Hence, the first dummy pattern DMP1 may not overlap with the trench TRCH. The first dummy pattern DMP1 may expose the emission structure EMS arranged on the trench TRCH. The first dummy pattern DMP1 may not be arranged on the first and second trenches TRCH1 and TRCH2, but may be arranged only on the first intermediate layer CGL1 on the pixel-defining layer PDL adjacent to the first and second anode electrodes AE1 and AE2.

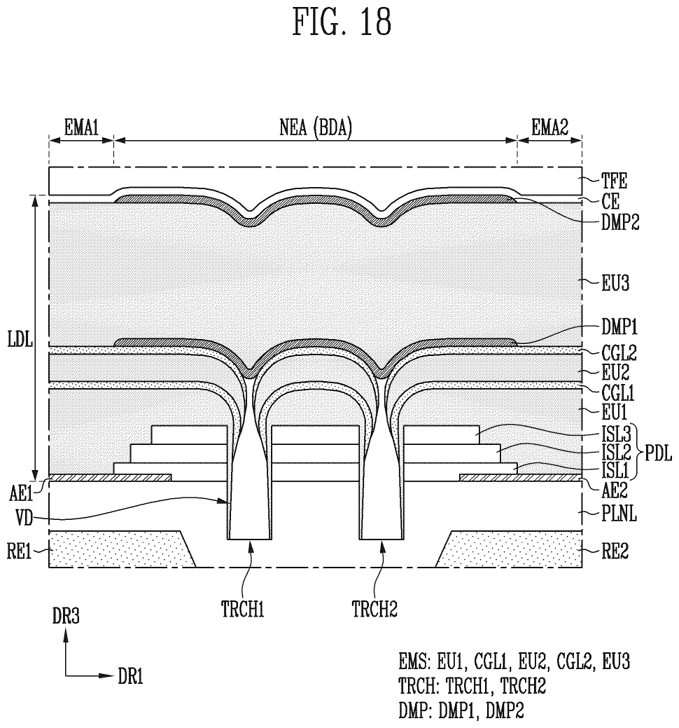

Referring to FIG. 2 and FIG. 18, the dummy pattern DMP may include a first dummy pattern DMP1 arranged between the second intermediate layer CGL2 and the third emission component EU3 and a second dummy pattern DMP2 arranged between the third emission component EU3 and the cathode electrode CE. Each of the first and second dummy patterns DMP1 and DMP2 may be connected on the first and second trenches TRCH1 and TRCH2 without being disconnected. The second dummy pattern DMP2 may be arranged directly below the cathode electrode CE in the non-emission area NEA (or the boundary area BDA) between the adjacent sub-pixels SP. In such embodiments, a second dummy pattern DMP2 may be formed on the third emission component EU3 with a thickness that is thick enough to prevent or substantially prevent the cathode electrode CE from being disconnected. The second dummy pattern DMP2 may be an organic insulation pattern including an organic material of greater resistance than the first emission component EU1, the second emission component EU2, and the third emission component EU3.

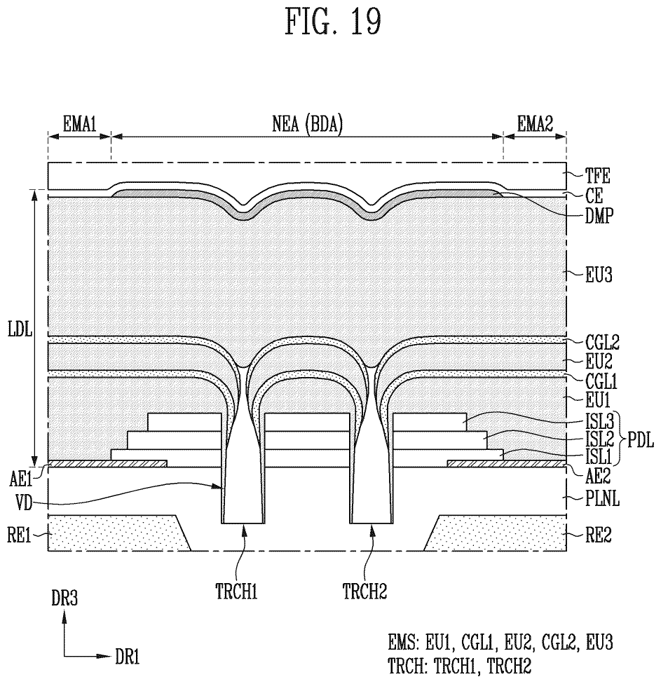

Referring to FIG. 2 and FIG. 19, the dummy pattern DMP may be arranged between the third emission component EU3 and the cathode electrode CE in the non-emission area NEA (or the boundary area BDA) between the adjacent sub-pixels SP. For example, the dummy pattern DMP may be arranged directly below cathode electrode CE in the non-emission area NEA between the adjacent sub-pixels SP. In such embodiments, the dummy pattern DMP may be formed on the third emission component EU3 with the thickness that is thick enough to prevent or substantially prevent the cathode electrode CE from being disconnected. The dummy pattern DMP may be an organic insulation pattern including an organic material of greater resistance than the first emission component EU1, the second emission component EU2, and the third emission component EU3.

The dummy pattern DMP arranged below the cathode electrode CE may block or reduce the likelihood of the lateral leakage generated in the non-emission area NEA between the adjacent sub-pixels SP from transmitting to the cathode electrode CE through the first emission component EU1, the first intermediate layer CGL1, the second emission component EU2, the second intermediate layer CGL2, and the third emission component EU3, such that the lateral leakage does not affect or has a reduced effect on the voltage applied to the cathode electrode CE. That is, this design should ensure that the lateral leakage does not affect or has a reduced effect on the voltage applied to the cathode electrode CE.

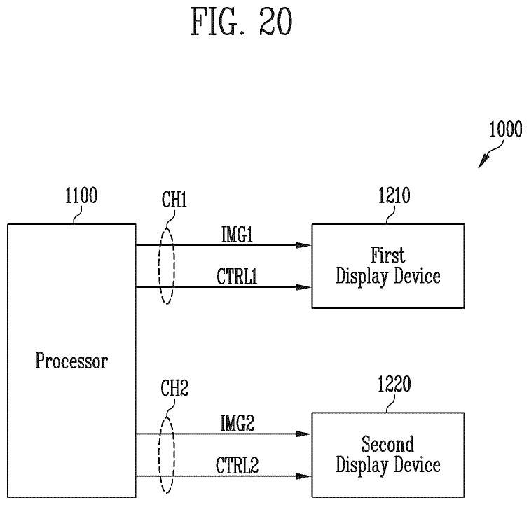

FIG. 20 is a schematic block diagram illustrating a display system 1000, according to one or more embodiments of the present disclosure.

Referring to FIG. 20, the display system 1000 may include a processor 1100 and one or more display devices 1210 and 1220.

The processor 1100 may perform one or more suitable tasks and calculations. In one or more embodiments, the processor 1100 may include an application processor, a graphic processor, a microprocessor, a central processing unit (CPU), and/or the like. The processor 1100 may be connected to other components of the display system 1000 via a bus system to control them.

FIG. 20 depicts that the display system 1000 includes the first and second display devices 1210 and 1220. The processor 1100 may be connected to the first display device 1210 via a first channel CH1 and to the second display device 1220 via a second channel CH2.

Through the first channel CH1, the processor 1100 may be to transmit first image data IMG1 and a first control signal CTRL1 to the first display device 1210. The first display device 1210 may display an image based on the first image data IMG1 and the first control signal CTRL1. The first display device 1210 may have the same configuration as the display device 100 described in reference to FIG. 1.

Through the second channel CH2, the processor 1100 may be to transmit second image data IMG2 and a second control signal CTRL2 to the second display device 1220. The second display device 1220 may display an image based on the second image data IMG2 and the second control signal CTRL2. The second display device 1220 may have the same configuration as the display device 100 described in reference to FIG. 1.

The display system 1000 may include a computing system for providing the image display function such as a portable computer, a mobile phone, a smart phone, a tablet personal computer, a smart watch, a watch phone, a portable multimedia player (PMP), a navigation device, and/or an ultra mobile personal computer (UMPC). In one or more embodiments, the display system 1000 may include at least one of a head mounted display (HMD), a virtual reality (VR) device, a mixed reality (MR) device, and/or an augmented reality (AR) device.

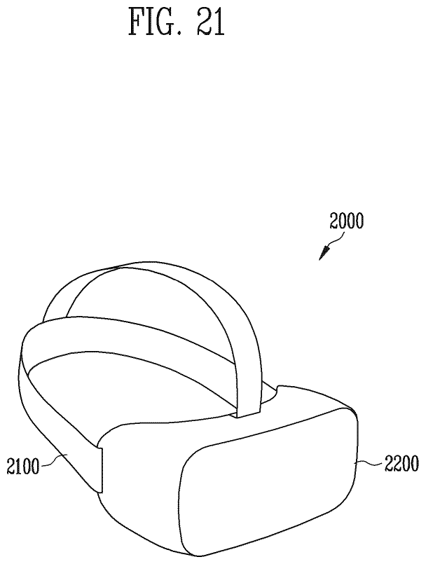

FIG. 21 is a schematic perspective view illustrating an example of an application of the display system 1000 of FIG. 20 according to one or more embodiments of the present disclosure.

Referring to FIG. 21, the display system 1000 of FIG. 20 may be applied to a head mounted display device 2000. The head mounted display device 2000 may be a wearable electronic device which may be worn on a user's head.

The head mounted display device 2000 may include a head mounting band 2100 and a display device receiving case 2200. The head mounting band 2100 may be connected to the display device receiving case 2200. The head mounting band 2100 may include a horizontal band and/or a vertical band for fixing the head mounted display device 2000 to the user's head. The horizontal band may be configured to be around (e.g., surround) a side of the user's head, and the vertical band may be configured to be around (e.g., surround) an upper part of the user's head. However, the present disclosure is not limited thereto. For example, the head mounting band 2100 may be implemented as a glasses frame type (kind), a helmet type (kind), and/or the like.

The display device receiving case 2200 may receive the first and second display devices 1210 and 1220 of FIG. 20. The display device receiving case 2200 may further receive the processor 1100 of FIG. 20.

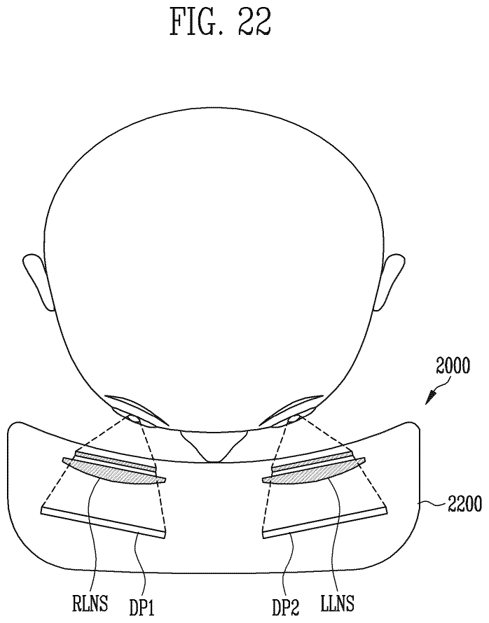

FIG. 22 is a schematic view illustrating a user wearing the head mounted display device 2000 of FIG. 21 according to one or more embodiments of the present disclosure.

Referring to FIG. 22, in the head mounted display device 2000, a first display panel DP1 of the first display device 1210 (see, e.g., FIG. 20) and a second display panel DP2 of the second display device 1220 (see, e.g., FIG. 20) are arranged. The head mounted display device 2000 may include one or more lenses LLNS and RLNS.

Within the display device receiving case 2200, the right eye lens RLNS may be arranged between the first display panel DP1 and a user's right eye. Within the display device receiving case 2200, the left eye lens LLNS may be arranged between the second display panel DP2 and a user's left eye.

An image outputted from the first display panel DP1 may be presented to the user's right eye through the right eye lens RLNS. The right eye lens RLNS may refract light from the first display panel DP1 to direct it to the user's right eye. The right eye lens RLNS may perform an optical function for controlling a viewing distance between the first display panel DP1 and the user's right eye.

The image output from the second display panel DP2 may be presented to the user's left eye through the left eye lens LLNS. The left eye lens LLNS may refract light from the second display panel DP2 to direct it toward the user's left eye. The left eye lens LLNS may perform an optical function to control a viewing distance between the second display panel DP2 and the user's left eye.

In one or more embodiments, each of the right eye lens RLNS and the left eye lens LLNS may include an optical lens having a pancake-shaped cross-section (e.g., a convex cross-section). In one or more embodiments, each of the right eye lens RLNS and the left eye lens LLNS may include a multi-channel lens including subareas with different optical properties. In such embodiments, each display panel outputs images corresponding to each of the subareas of the multi-channel lens, and the output images may be presented to the user through each of the corresponding subareas.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic apparatus (device), device for manufacturing the display device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate defining a first sub-pixel and a second sub-pixel adjacent to each other, each of the first sub-pixel and the second sub-pixel comprising a first electrode;
a pixel-defining layer on the first electrodes of the first and second sub-pixels;
a first emission component to emit light and on the first electrodes of the first and second sub-pixels and the pixel-defining layer;
a first intermediate layer on the first emission component;
a second emission component to emit light and on the first intermediate layer; and
a second electrode on the second emission component,
wherein at least part of the pixel-defining layer is recessed to form a trench in a boundary area of the first sub-pixel and the second sub-pixel,
a dummy pattern is between the first intermediate layer and the second electrode in the boundary area, and
the dummy pattern is an insulation pattern comprising an organic material.

2. The display device according to claim 1, wherein the organic material comprises parylene.

3. The display device according to claim 1, wherein the dummy pattern is directly on the first intermediate layer and the first intermediate layer is a conductor.

4. The display device according to claim 1, wherein the second emission component comprises a second hole transporter, a second emission layer, and a second electron transporter sequentially stacked on the first intermediate layer, and
the dummy pattern is between the first intermediate layer and the second hole transporter.

5. The display device according to claim 1, wherein the second emission component comprises a second hole transporter, a second emission layer, and a second electron transporter sequentially stacked on the first intermediate layer, and
the dummy pattern is on the second hole transporter.

6. The display device according to claim 1, wherein the dummy pattern is between the second emission component and the second electrode.

7. The display device according to claim 1, wherein the first emission component and the first intermediate layer are disconnected at the trench,
the second emission component at the first sub-pixel and the second emission component at the second sub-pixel are connected, and
the dummy pattern is not disconnected at the trench.

8. The display device according to claim 1, wherein the dummy pattern is not on the trench.

9. The display device according to claim 1, wherein the dummy pattern is in a non-emission area between an emission area of the first sub-pixel and an emission area of the second sub-pixel and corresponds to the pixel-defining layer.

10. The display device according to claim 1, wherein the dummy pattern is across a part of an emission area of the first sub-pixel, a non-emission area between the emission area of the first sub-pixel and an emission area of the second sub-pixel, and a part of the emission area of the second sub-pixel.

11. The display device according to claim 1, further comprising a planarization layer below the first electrodes of the first and second sub-pixels,
the trench is penetrating through the pixel-defining layer in a non-emission area between an emission area of the first sub-pixel and an emission area of the second sub-pixel, and is partially penetrating through the planarization layer, and
the trench defines a void surrounded by the planarization layer, the first emission component, the first intermediate layer, and the dummy pattern.

12. The display device according to claim 1, further comprising:
a third emission component to emit light and between the first electrode and the first emission component; and
a second intermediate layer between the third emission component and the first emission component, and
the third emission component and the second intermediate layer are each disconnected at the trench.

13. The display device according to claim 12, wherein the dummy pattern comprises:
a first dummy pattern between the first intermediate layer and the second emission component; and
a second dummy pattern between the second intermediate layer and the first emission component.

14. The display device according to claim 13, wherein the second dummy pattern is disconnected at the trench.

15. The display device according to claim 13, wherein the second dummy pattern is not on the trench.

16. The display device according to claim 13, wherein the dummy pattern comprises:
a first dummy pattern between the first intermediate layer and the second emission component; and
a second dummy pattern between the second emission component and the second electrode.

17. The display device according to claim 13, further comprising a planarization layer below the first electrodes of the first and second sub-pixels,
the trench is penetrating through the pixel-defining layer in a non-emission area between an emission area of the first sub-pixel and an emission area of the second sub-pixel, and is partially penetrating through the planarization layer, and
the trench defines a void surrounded by the planarization layer, the third emission component, the second intermediate layer, the first emission component, the first intermediate layer, and the dummy pattern.

18. The display device according to claim 17, wherein each of the first emission component to the third emission component comprises a hole transporter, an emission layer, and an electronic transporter which are stacked in sequence.

19. A wearable electronic device comprising:
a display panel; and
a lens on the display panel,
wherein the display panel comprises:
a substrate defining a first sub-pixel and a second sub-pixel adjacent to each other, each of the first and second sub-pixel comprising a first electrode on the substrate; a pixel-defining layer on the first electrodes of the first and second sub-pixels;
a first emission component to emit light and on the first electrodes of the first and second sub-pixels and the pixel-defining layer;
a first intermediate layer on the first emission component;
a second emission component to emit light and on the first intermediate layer; and
a second electrode on the second emission component,
wherein at least part of the pixel-defining layer is recessed to form a trench in a boundary area of the first sub-pixel and the second sub-pixel,
a dummy pattern is between the first intermediate layer and the second electrode in the boundary area, and
the dummy pattern is an organic insulation pattern comprising parylene.

20. A method of manufacturing a display device, the method comprising:
forming an anode electrode on a planarization layer on a substrate, the substrate defining sub-pixels;
forming a pixel-defining layer on the planarization layer and the anode electrode;
forming a first emission component which comprises a first emission layer on the anode electrode and the pixel-defining layer;
forming a first intermediate layer on the first emission component;
disposing a mask above the first intermediate layer and then performing a vacuum deposition process to form a dummy pattern in one area of the first intermediate layer corresponding to a boundary area between adjacent sub-pixels;
forming a second emission component comprising a second emission layer on the dummy pattern; and
forming a cathode electrode on the second emission component,
wherein the dummy pattern is an organic insulation pattern comprising parylene.
